(19) United States
(12) Patent Application Publication
(10) Pub. No.: US 2026/0177292 A1
(43) Pub. Date: Jun. 25, 2026

(54) THERMOELECTRIC ELEMENT, METHOD FOR MANUFACTURING THERMOELECTRIC ELEMENT, AND REFRIGERATOR INCLUDING THERMOELECTRIC ELEMENT

(71) Applicant: SAMSUNG ELECTRONICS CO., LTD., Suwon-si (KR)

(72) Inventors: Jinju KIM, Suwon-si (KR); Kyunghwan LEE, Suwon-si (KR); Kwangjoo KIM, Suwon-si (KR)

(73) Assignee: SAMSUNG ELECTRONICS CO., LTD., Suwon-si (KR)

(21) Appl. No.: 19/436,713

(22) Filed: Dec. 30, 2025

Related U.S. Application Data
(63) Continuation of application No. PCT/KR2025/021886, filed on Dec. 16, 2025.

(30) Foreign Application Priority Data
Dec. 23, 2024 (KR) 10-2024-0193965

(51) Int. Cl. F25B 21/02; F25B 7/00; H10N 10/10; H10N 10/82; H10N 10/853; H10N 19/00

(52) U.S. Cl. CPC F25B 21/02; F25B 7/00; H10N 10/10; H10N 10/82; H10N 10/853; F25B 2321/003; H10N 19/101

(57) ABSTRACT

A thermoelectric element, and a refrigerator including the thermoelectric element, including a thermoelectric material layer including a plurality of anchor recesses on upper and lower surfaces of the thermoelectric material layer, the plurality of anchor recesses having a width of 0.1 μm to 10 μm and being formed on cracks on the upper and lower surfaces of the thermoelectric material layer; and a first diffusion barrier layer disposed on the thermoelectric material layer, wherein a portion of the first diffusion barrier layer penetrates into the plurality of anchor recesses.

### CROSS-REFERENCE TO RELATED APPLICATIONS

This application is a by-pass continuation application of International Application No. PCT/KR2025/021886, filed on Dec. 16, 2025, which is based on and claims priority to Korean Patent Application No. 10-2024-0193965, filed on Dec. 23, 2024, in the Korean Intellectual Property Office, the disclosures of which are incorporated by reference herein their entireties.

### TECHNICAL FIELD

Various embodiments of the disclosure relate to a thermoelectric element, a method for manufacturing thermoelectric element, and a refrigerator including a thermoelectric element.

### BACKGROUND ART

A refrigerator is a home appliance that cools food in a storage compartment or stores food at low temperatures to prevent food spoilage or deterioration and to keep food fresh. The storage compartment includes a refrigerating compartment maintained at about 0 to 5 degrees Celsius for refrigerated storage of food, and a freezing compartment maintained at about 0 to minus 30 degrees Celsius for frozen storage of food. A door is provided on a front surface of a main body to open and close the storage compartment. The door is rotatably provided on the front surface of the main body to open and close the storage compartment. Further, the door may be provided as a drawer-type door to open and close the storage compartment.

Meanwhile, the refrigerator may include a storage compartment capable of receiving food and a cold air supply device for cooling the storage compartment. The refrigerator may use the cold air supply device to freeze/refrigerate the storage compartment to keep food stored in the storage compartment fresh for a long period. Generally, cold air supply devices may be classified into a refrigerating cycle device using a refrigerating cycle and a Peltier cooling device using a Peltier element according to a method of generating cold air.

For example, a refrigerating cycle device may obtain cold air by circulating refrigerant along a closed circuit composed of a compressor, a condenser, an expander, and an evaporator.

For example, a Peltier cooling device may obtain cold air using a thermoelectric element that generates a Peltier effect. Here, the Peltier effect may refer to a phenomenon in which when a potential difference is applied to two opposite sides of an object, heat flows along with current, causing one side to be heated and the other side to be cooled.

The above-described information may be provided as related art for the purpose of helping understanding of the disclosure. No claim or determination is made as to whether any of the foregoing is applicable as background art in relation to the disclosure.

### DISCLOSURE OF INVENTION

### Solution to Problems

Aspects of embodiments of the disclosure will be set forth in part in the description which follows and, in part, will be apparent from the description, or may be learned by practice of the presented embodiments.

According to an embodiment of the disclosure, a thermoelectric element includes a thermoelectric material layer including a plurality of anchor recesses on upper and lower surfaces of the thermoelectric material layer, the plurality of anchor recesses having a width of 0.1 μm to 10 μm and being formed on cracks on the upper and lower surfaces of the thermoelectric material layer; and a first diffusion barrier layer disposed on the thermoelectric material layer, wherein a portion of the first diffusion barrier layer penetrates into the plurality of anchor recesses.

According to an embodiment of the disclosure, at least a portion of anchor recesses of the plurality of anchor recesses may have a dendrite or rod shape.

According to an embodiment of the disclosure, at least a portion of the plurality of anchor recesses may have a depth of 0.1 μm to 10 μm.

According to an embodiment of the disclosure, the first diffusion barrier layer may include nickel.

According to an embodiment of the disclosure, the first diffusion barrier layer may have a thickness of 0.1 μm to 2.0 μm.

According to an embodiment of the disclosure, the thermoelectric element may further include a second diffusion barrier layer including a nickel-phosphorus alloy structure, and disposed on the first diffusion barrier layer; and a third diffusion barrier layer including a nickel-phosphorus alloy structure, and disposed on the second diffusion barrier layer.

According to an embodiment of the disclosure, a total thickness of the first diffusion barrier layer, the second diffusion barrier layer, and the third diffusion barrier layer may be 3.0 μm to 20.0 μm.

According to an embodiment of the disclosure, 20% to 30% of a total volume of the first diffusion barrier layer, the second diffusion barrier layer, and the third diffusion barrier layer may penetrate into the plurality of anchor recesses. a phosphorus content of the second diffusion barrier layer may be 1 wt % to 8 wt %. A phosphorus content of the third diffusion barrier layer may be 1 wt % to 8 wt %.

According to an embodiment of the disclosure, the thermoelectric material layer may include bismuth. A bismuth weight content of portions of the thermoelectric material layer forming the plurality of anchor recesses may be less than an average bismuth weight content of the thermoelectric material layer.

According to an embodiment of the disclosure, a refrigerator includes a main body; a storage compartment in the main body; and a cold air supply device configured to supply cold air to the storage compartment, the cold air supply device including a thermoelectric module, wherein the thermoelectric module includes a lower substrate, a lower conductive pattern layer disposed on the lower substrate, a plurality of thermoelectric elements disposed on the lower conductive pattern layer, an upper conductive pattern layer disposed on the plurality of thermoelectric elements, and an upper substrate disposed on the upper conductive pattern layer, and each thermoelectric element of the plurality of thermoelectric elements includes a thermoelectric material layer including a plurality of anchor recesses on upper and lower surfaces of the thermoelectric material layer, the plurality of anchor recesses having a width of 0.1 μm to 10.0 μm and being formed on cracks on the upper and lower surfaces of the thermoelectric material layer, and a first diffusion barrier layer disposed on the thermoelectric material layer, wherein a portion of the first diffusion barrier layer penetrates into the plurality of anchor recesses.

According to an embodiment of the disclosure, at least a portion of anchor recesses of the plurality of anchor recesses may have a dendrite or rod shape.

According to an embodiment of the disclosure, at least a portion of the plurality of anchor recesses may have a depth of 0.1 μm to 10 μm.

According to an embodiment of the disclosure, the first diffusion barrier layer may include nickel.

According to an embodiment of the disclosure, the first diffusion barrier layer may have a thickness of 0.1 μm to 2.0 μm.

According to an embodiment of the disclosure, each thermoelectric element of the plurality of thermoelectric elements may include a second diffusion barrier layer including a nickel-phosphorus alloy structure, and disposed on the first diffusion barrier layer, and a third diffusion barrier layer including a nickel-phosphorus alloy structure, and disposed on the second diffusion barrier layer.

According to an embodiment of the disclosure, a total thickness of the first diffusion barrier layer, the second diffusion barrier layer, and the third diffusion barrier layer may be 3.0 μm to 20.0 μm.

According to an embodiment of the disclosure, 20% to 30% of a total volume of the first diffusion barrier layer, the second diffusion barrier layer, and the third diffusion barrier layer may penetrate into the plurality of anchor recesses.

According to an embodiment of the disclosure, a phosphorus content of the second diffusion barrier layer may be 1 wt % to 8 wt %. A phosphorus content of the third diffusion barrier layer may be 1 wt % to 8 wt %.

According to an embodiment of the disclosure, the thermoelectric material layer may include bismuth. A bismuth weight content of portions of the thermoelectric material layer forming the plurality of anchor recesses may be less than an average bismuth weight content of the thermoelectric material layer.

Effects achievable in example embodiments of the disclosure are not limited to the above-mentioned effects, but other effects not mentioned may be apparently derived and understood by one of ordinary skill in the art to which example embodiments of the disclosure pertain, from the following description. In other words, unintended effects in practicing embodiments of the disclosure may also be derived by one of ordinary skill in the art from example embodiments of the disclosure.

### BRIEF DESCRIPTION OF DRAWINGS

These and/or other aspects of the disclosure will become apparent and more readily appreciated from the following description of embodiments, taken in conjunction with the accompanying drawings listed below.

FIG. 1 is a view schematically illustrating an inner/outer appearance of a refrigerator according to an embodiment of the disclosure.

FIG. 2 is a functional block diagram schematically illustrating a configuration of a refrigerator according to an embodiment of the disclosure in terms of functions and controls.

FIG. 3 is a perspective view illustrating a thermoelectric module according to an embodiment.

FIG. 4 is a side cross-sectional view illustrating a thermoelectric module according to an embodiment.

FIG. 5 is a side cross-sectional view illustrating a thermoelectric element according to an embodiment.

FIG. 6 is a flowchart for describing a method for manufacturing a thermoelectric element according to an embodiment.

FIG. 7 is an example view illustrating a process of preparing thermoelectric pillars of a thermoelectric element according to an embodiment.

FIG. 8 is a diagram observing a side cross-section of a portion of a general thermoelectric element.

FIGS. 9A, 9B, 9C, and 9D are experimental examples observing a process of surface changes during manufacturing of a thermoelectric element according to an embodiment.

FIG. 10 is an experimental example of observing a side cross-sectional view illustrating a p-type thermoelectric element according to an embodiment with an electron microscope.

FIG. 11 is an experimental example of observing a side cross-sectional view illustrating an n-type thermoelectric element according to an embodiment with an electron microscope.

FIG. 12 is an experimental example for identifying an enhancement degree of adhesion force of a thermoelectric element according to an embodiment.

FIGS. 13A and 13B are experimental examples for observing surface roughness when anchor recesses are formed by a laser irradiation method.

FIGS. 14A and 14B are experimental examples for observing surface roughness of a thermoelectric element according to an embodiment.

FIG. 15A is an experimental example of observing a side cross-section of a thermoelectric element according to an embodiment.

FIG. 15B is a graph measuring element content of a portion corresponding to line A-B of FIG. 15A.

FIG. 16 is an experimental example for identifying adhesion force according to a method of plating a first diffusion barrier layer in a thermoelectric element according to an embodiment.

Reference may be made to the accompanying drawings in the following description, and specific examples that may be practiced are shown as examples within the drawings. Other examples may be utilized and structural changes may be made without departing from the scope of the various examples.

### MODE FOR THE INVENTION

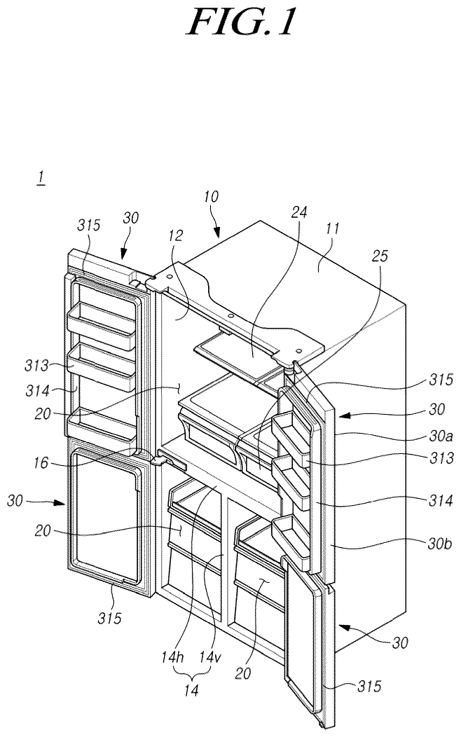

Various embodiments of the disclosure are merely exemplified herein with reference to FIGS. 1 to 16, to describe the principle of the disclosure, and should not be interpreted as limiting the scope of the disclosure. Those skilled in the art will understand that the principle of the disclosure may be implemented in any appropriately disposed system or device.

It should be appreciated that various embodiments of the disclosure and the terms used therein are not intended to limit the technological features set forth herein to particular embodiments and include various changes, equivalents, or replacements for a corresponding embodiment.

With regard to the description of the drawings, similar reference numerals may be used to refer to similar or related elements.

It is to be understood that a singular form of a noun corresponding to an item may include one or more of the things, unless the relevant context clearly indicates otherwise.

As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases.

The term “and/or” may denote a combination(s) of a plurality of related components as listed or any of the components.

As used herein, such terms as “1st” and “2nd,” or “first” and “second” may be used to simply distinguish a corresponding component from another, and does not limit the components in other aspect (e.g., importance or order).

As used herein, the terms “cooling device” and “cold air supply device” may be interchangeably used.

As used herein, the terms ‘front surface,’ ‘rear surface,’ ‘upper surface,’ ‘side surface,’ ‘left side,’ ‘right side,’ ‘upper portion,’ and ‘lower portion’ are defined with respect to the drawings, and the shape and position of each component are not limited by the terms.

It will be further understood that the terms “comprise” and/or “have,” as used herein, specify the presence of stated features, integers, steps, operations, elements, and/or components, but do not preclude the presence or addition of one or more other features, integers, steps, operations, elements, components, and/or groups thereof.

It will be understood that when a component is referred to as “connected to,” “coupled to”, “supported on,” or “contacting” another component, the components may be connected to, coupled to, supported on, or contact each other directly or via a third component.

Throughout the specification, when one component is positioned “on” another component, the first component may be positioned directly on the second component, or other component(s) may be positioned between the first and second component.

The “main body” may include an inner case, an outer case disposed outside the inner case, and an insulator provided between the inner case and the outer case.

The refrigerator according to an embodiment may include a main body.

The “inner case” may include at least one of a case, a plate, a panel, or a liner forming a storage compartment. The inner case may be formed as a single body or may be formed by assembling a plurality of plates. The “outer case” may form the outer appearance of the main body and may be coupled to an outer side of the inner case so that the insulator is disposed between the inner case and the outer case.

The “insulator” may insulate the inside of the storage compartment and the outside of the storage compartment so that the temperature inside the storage compartment is maintained at a set appropriate temperature without being affected by the environment outside the storage compartment. According to an embodiment, the insulator may include a foam insulator. The foam insulator may be formed by injecting and foaming a urethane foam formed by mixing polyurethane and a foaming agent between the inner case and the outer case.

According to an embodiment, the insulator may further include a vacuum insulator in addition to the foam insulator, or the insulator may be composed of only a vacuum insulator instead of the foam insulator. The vacuum insulator may include a core material and an outer cover material that accommodates the core material and seals the inside at a pressure close to vacuum or vacuum. However, the insulator is not limited to the foam insulator or the vacuum insulator, and may include various materials that may be used for insulation.

The “storage compartment” may include a space limited by the inner case. The storage compartment may further include an inner case that limits a space corresponding to the storage compartment. Various items such as food, medicine, cosmetics, etc. may be stored in the storage compartment, and the storage compartment may be formed so that at least one side thereof is opened to take in and out the items.

The refrigerator may include one or more storage compartments. When two or more storage compartments are formed in the refrigerator, each storage compartment may have a different use and may be maintained at a different temperature. To that end, each storage compartment may be partitioned from each other by a partition wall including an insulator.

The storage compartment may be provided to be maintained in an appropriate temperature range according to the use, and may include a “refrigerating compartment”, a “freezing compartment”, or an “adjustable-temperature compartment” divided by the use and/or temperature range thereof. The refrigerating compartment may be maintained at a temperature suitable for refrigerating and storing items, and the freezing compartment may be maintained at a temperature suitable for freezing and storing items. The term “refrigerating” may mean cooling the item to the extent that the item is not frozen, and for example, the refrigerating compartment may be maintained in the range of 0 degrees Celsius to 7 degrees Celsius. The term “freezing” may mean cooling the item to freeze or remain frozen, and for example, the freezing compartment may be maintained in the range of minus 20 degrees Celsius to minus 1 degree Celsius. The adjustable-temperature compartment may be used as any one of the refrigerating compartment or the freezing compartment regardless of the user's selection.

The storage compartment may be referred to as a “vegetable compartment”, a “fresh compartment”, a “cooling compartment”, an “ice-making compartment”, and the like, in addition to the names “refrigerating compartment”, “freezing compartment”, and “adjustable-temperature compartment”, and the terms “refrigerating compartment”, “freezing compartment”, and “adjustable-temperature compartment” used below should be understood to collectively mean storage compartments having their respective corresponding uses and temperature ranges.

According to an embodiment, the refrigerator may include at least one door configured to open and close one open side of the storage compartment. The door may be provided to open and close each of one or more storage compartments, or one door may be provided to open and close a plurality of storage compartments. The door may be rotatably or slidably installed on the front surface of the main body.

The “door” may be configured to seal the storage compartment when the door is closed. Like the main body, the door may include an insulator to insulate the storage compartment when the door is closed.

According to an embodiment, the door may include a door outer plate forming a front surface of the door, a door inner plate forming a rear surface of the door and facing the storage compartment, an upper cap, a lower cap, and a door insulator provided thereinside.

A gasket may be provided on the edge of the door inner plate to seal the storage compartment by being in close contact with the front surface of the main body when the door is closed. The door inner plate may include a dyke protruding rearward to mount a door basket capable of storing an object.

According to an embodiment, the door may include a door body and a front panel detachably coupled to a front side of the door body and forming a front surface of the door. The door body may include a door outer plate forming a front surface of the door body, a door inner plate forming a rear surface of the door body and facing the storage compartment, an upper cap, a lower cap, and a door insulator provided thereinside.

The refrigerator may be classified into a French door type, a side-by-side type, a bottom mounted freezer (BMF), a top mounted freezer (TMF), or a one-door refrigerator according to the arrangement of the door and the storage compartment.

According to an embodiment, the refrigerator may include a cold air supply device configured to supply cold air to the storage compartment.

The “cold air supply device” may include a machine, an instrument, an electronic device, and/or a system combining the machine, the instrument, and the electronic device capable of generating cold air and guiding the cold air to cool the storage compartment.

According to an embodiment, the cold air supply device may generate cold air through a refrigerating cycle including processes of compressing, condensing, expanding, and evaporating the refrigerant. To that end, the cold air supply device may include a refrigerating cycle device having a compressor, a condenser, an expansion device, and an evaporator capable of driving the refrigerating cycle. According to an embodiment, the cold air supply device may include a semiconductor such as a thermoelectric element. The thermoelectric element may cool the storage compartment by heating and cooling through the Peltier effect.

According to an embodiment, the refrigerator may include a machine room in which at least some components belonging to the cold air supply device are arranged.

The “machine room” may be provided to be partitioned and insulated from the storage compartment to prevent heat generated from components disposed in the machine room from being transferred to the storage compartment. The inside of the machine room may be configured to communicate with the outside of the main body to dissipate heat from components disposed inside the machine room.

According to an embodiment, the refrigerator may include a dispenser provided on the door to provide water and/or ice. The dispenser may be provided on the door to be accessed by the user without opening the door.

According to an embodiment, the refrigerator may include an ice maker provided to generate ice. The ice maker may include an ice making tray storing water, an ice maker separating ice from the ice making tray, and an ice bucket storing ice generated in the ice making tray.

According to an embodiment, the refrigerator may include a controller for controlling the refrigerator.

The “controller” may include a memory storing or recording a program and/or data for controlling the refrigerator, and a processor outputting a control signal for controlling the cold air supply device according to the program and/or data stored in the memory.

The memory stores or records various information, data, instructions, programs, etc. necessary for the operation of the refrigerator. The memory may store temporary data generated while generating a control signal for controlling components included in the refrigerator. The memory may include at least one of a volatile memory and a non-volatile memory or a combination thereof.

The processor controls the overall operation of the refrigerator. The processor may control the components of the refrigerator by executing a program stored in the memory. The processor may include a separate NPU that performs the operation of the artificial intelligence model. The processor may include a central processing unit, a graphics-only processor (GPU), and the like. The processor may generate a control signal for controlling the operation of the cold supply device. For example, the processor may receive temperature information about the storage compartment from the temperature sensor, and generate a cooling control signal for controlling the operation of the cold air supply device based on the temperature information about the storage compartment.

Further, the processor may process the user input of the user interface according to the program and/or data stored/stored in the memory, and control the operation of the user interface. The user interface may be provided using an input interface and an output interface. The processor may receive a user input from the user interface. Further, the processor may transfer a display control signal and image data for displaying an image on the user interface to the user interface in response to the user input.

The processor and the memory may be provided integrally or separately. The processor may include one or more processors. For example, the processor may include a main processor and at least one sub-processor. The memory may include one or more memories.

The refrigerator may include a processor and a memory controlling all components included in the refrigerator, and a plurality of processors and a plurality of memories individually controlling the components of the refrigerator. For example, the refrigerator may include a processor and a memory controlling the operation of the cold air supply device according to the output of the temperature sensor. Further, the refrigerator may include a separate processor and a separate memory controlling the operation of the user interface according to a user input.

The communication module may communicate with an external device such as a server, a mobile device, another home appliance, or the like through an access point (AP). The AP may connect the local area network (LAN) to which the refrigerator or the user equipment is connected to the wide area network (WAN) to which the server is connected. The refrigerator or the user device may be connected to the server through the wide area network (WAN).

The input interface may include a key, a touch screen, a microphone, and the like. The input interface may receive a user input and transfer the user input to the processor.

The output interface may include a display, a speaker, and the like. The output interface may output various notifications, messages, information, and the like generated by the processor.

FIG. 1 is a view schematically illustrating an inner/outer appearance of a refrigerator according to an embodiment of the disclosure.

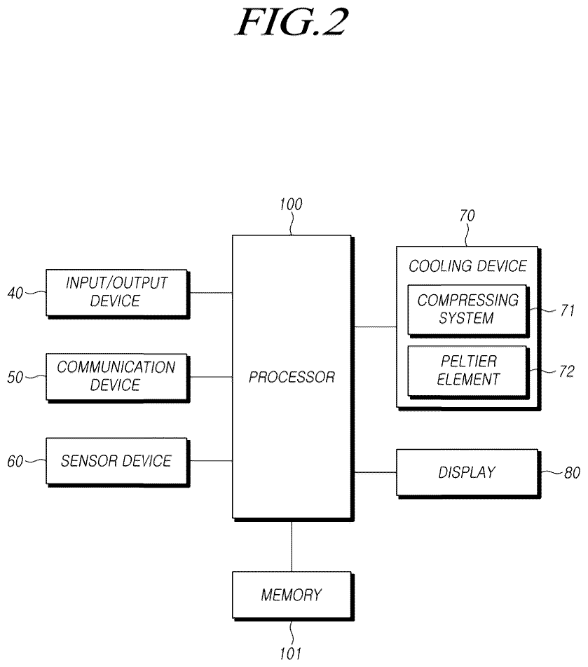

All features, components, and/or arrangement relationships between components illustrated in FIG. 1 may be included alone or in combination with the features, components, and arrangement relationships between components described in other drawings of the disclosure. Likewise, all features, components, and/or arrangement relationships between components described in connection with FIGS. 2 to 16 may be included alone or in combination with the features, components, and arrangement relationships between components described in connection with FIG. 2.

Referring to FIG. 1, a refrigerator 1 according to an embodiment may include a main body 10. The main body 10 may include an outer case 11 and an inner case 12 disposed inside the outer case 11. The outer case 11 may be provided to form at least a portion of the outer appearance of the main body 10. In an example, the outer case 11 may be configured to include a metal material having excellent durability and aesthetics. The inner case 12 may be provided to define a space of the storage compartment 20. The inner case 12 may include a case, a plate, a panel, and/or a liner forming the storage compartment 20. The inner case 12 may be formed as a single body or may be formed by assembling a plurality of plates. In an example, the inner case 12 may be integrally injection-molded using a plastic material, but the disclosure is not limited thereto.

According to an embodiment, an accommodation space may be formed between the outer case 11 and the inner case 12. An insulator for insulating the storage compartment 20 may be disposed in at least a portion of the accommodation space. The insulator may insulate the inside of the storage compartment 20 and the outside of the storage compartment 20 so that the temperature inside the storage compartment 20 may be maintained at a set appropriate temperature without being affected by the external environment of the storage compartment 20.

According to an embodiment, the insulator may include a foam insulator. In an example, after fixing the inner case 12 and the outer case 11 with a jig or the like, the foam insulator may be formed by injecting and foaming a urethane foam mixed with polyurethane and a foaming agent into an accommodation space between the inner case 12 and the outer case 11. According to an embodiment, the insulator may include a vacuum insulator in addition to the foam insulator or in place of the foam insulator. The vacuum insulator may include a core material and an outer cover material that accommodates the core material and seals the inside at a pressure close to vacuum or vacuum. The vacuum insulator may further include an adsorbent that adsorbs gas and moisture to maintain a stable vacuum state. The insulator of the refrigerator 1 is not limited to the foam insulator or vacuum insulator described above, but may be configured using various materials that may be used for insulation.

According to an embodiment, the refrigerator 1 may include a storage compartment 20. The storage compartment 20 may store food. Food includes things that may be eaten or drunk, and specifically, may include meat, fish, seafood, fruits, vegetables, water, ice, beverages, kimchi, or alcoholic beverages such as wine. Drugs and cosmetics may be stored in the storage compartment 20 in addition to food, but there is no limitation on items that may be stored in the storage compartment 20.

According to an embodiment, the refrigerator 1 may include one or more storage compartments 20. When two or more storage compartments 20 are formed in the refrigerator 1, each storage compartment may have a different use and may be maintained at a different temperature. To that end, the storage compartments 20 may be partitioned from each other by a partition wall 14 including an insulator. In an example, the storage compartment may be referred to as a “refrigerating compartment”, a “freezing compartment”, or a “variable temperature compartment” according to the use and/or the temperature range. Refrigerating may refer to cooling food to the extent that the food is not frozen, and for example, the refrigerating compartment may be maintained in the range of 0 degrees Celsius to 7 degrees Celsius. Freezing may mean freezing food or cooling food to remain frozen, and for example, the freezing compartment may be maintained in the range of minus 20 degrees Celsius to minus 1 degree Celsius. The variable temperature compartment may refer to a storage compartment where at a predetermined variable temperature may be maintained by the user's selection or regardless of the user's selection. According to an embodiment, one storage compartment may be provided so that a portion thereof is used as a refrigerating compartment and the remaining portion thereof is used as a freezing compartment. Storage compartments may be referred to by various names such as “vegetable compartment”, “fresh compartment”, “cooling compartment”, and “ice making compartment” in addition to the above-described names such as “refrigeration compartment”, “freezing compartment”, and “variable temperature compartment”.

According to an embodiment, the number, size, and/or shape of the storage compartment 20 may vary depending on the shape or position of the partition wall 14. According to an embodiment, the partition wall 14 may be integrally formed with the main body 10. According to an embodiment, the partition wall 14 may be a separate partition provided separately from the main body 10 and assembled to the main body 10.

According to an embodiment, the storage compartment 20 may be partitioned left and right by a vertical partition wall 14v (a partition wall extending in the vertical direction). The size of the storage compartment 20 partitioned left and right may vary depending on the position of the vertical partition wall 14v. For example, the storage compartment 20 in which the vertical partition wall 14v is provided in the middle and partitioned left and right may be provided in mirror symmetry. According to an embodiment, there may be a plurality of vertical partition walls. When there are a plurality of vertical partition walls, the storage compartment may be divided into three or more storage compartments along the left and right directions.

According to an embodiment, the storage compartment 20 may be vertically partitioned by a horizontal partition wall 14h (a partition wall extending in the horizontal direction). The size of the storage compartment 20 divided vertically may vary depending on the position of the horizontal partition wall 14h. According to an embodiment, there may be a plurality of horizontal partition walls. When there are a plurality of horizontal partition walls, the storage compartment may be divided into three or more storage compartments in the vertical direction.

According to an embodiment, the refrigerator may be configured to include a plurality of storage compartments having various sizes and shapes according to various combinations of the vertical partition wall and the horizontal partition wall.

According to an embodiment, a plurality of shelves 24 and/or a plurality of storage containers 25 may be provided inside the storage compartment 20. Each of the plurality of shelves 24 and the plurality of storage containers 25 may be separable from an inner space of the storage compartment 20.

According to an embodiment, each storage compartment 20 may be formed so that at least one side thereof is open for receiving and receiving food. According to an embodiment, the refrigerator 1 may include each door 30 for opening and closing each storage compartment 20. In an example, the door 30 may be disposed on the front surface of the main body 10 and the storage compartment 20 to open and close the storage compartment 20. The door 30 may be configured to seal the storage compartment 20 while the door is closed. Like the main body 10, the door 30 may include an insulator to insulate the storage compartment 20 from the external environment while the door 30 is closed.

According to an embodiment, the door 30 may be configured to be opened and closed by rotating about the hinge 16, but the disclosure is not limited thereto. In an example, the door may be configured to be opened and closed in a sliding manner.

According to an embodiment, the door 30 may include a door panel 30a and/or a door body 30b. The door panel 30a and the door body 30b may be detachably coupled to each other. For example, one side of the door body 30b may be fixed to the main body 10 by the hinge 16. The door panel 30a may form a portion of the front outer appearance of the refrigerator 1. Accordingly, the door panel 30a may serve as an important element of aesthetics when the refrigerator 1 is disposed indoors. The door panel 30a may have various colors and/or various designs and may be configured to be replaceable so that the user may decorate the front exterior of the refrigerator 1 according to his/her taste. According to an embodiment, the door panel 30a and the door body 30b may be integrally formed with each other.

According to an embodiment, the door 30 may include a door handle (not shown), a door shelf 313, a shelf support 314, and/or a gasket 315. The user may open and close the door 30 using the door handle. The door handle may be recessed on the bottom surface or the top surface of the door 30, or may protrude from the front surface of the door 30, but is not limited to a specific shape.

According to an embodiment, the door shelf 313 may be provided to receive food. Shelf supports 314 may be provided on both left and right sides of the door shelf 313 to support the door shelf 313. The shelf support 314 may extend vertically from, e.g., the door 30. For example, the shelf support 314 may protrude from the rear surface (the inner surface facing the storage compartment 20) of the door 30 toward the storage compartment 20 and may be provided to extend in the vertical direction. The shelf support 314 may be provided as a separate component separable from the door 30, or may be integrally formed with the door 30.

According to an embodiment, the gasket 315 may be provided to surround an edge of the door body 30b. The gasket 315 may be provided to seal a gap between the main body 10 and the door 30 in a state in which the door 30 is closed.

According to an embodiment, the refrigerator 1 may include a cooling device. The cooling device may include a machine, an instrument, an electronic device, and/or a system combining the machine, the instrument, and the electronic device capable of generating cold air and guiding the generated cold air to the storage compartment to cool the storage compartment. A plurality of cooling devices may be provided, and different types of cooling devices may be included. In an example, the cooling device may include at least a portion of a compressing system, or a Peltier element. For example, the refrigerator 1 may include only a compressing system, only a Peltier element, or both a compressing system and a Peltier element together in a hybrid form.

In an example, the cooling device may be provided inside the main body 10 to supply cold air to each of the storage compartments 20, for example.

FIG. 2 is a functional block diagram schematically illustrating a configuration of a refrigerator according to an embodiment of the disclosure in terms of functions and controls.

All features, components, and/or arrangement relationships between components illustrated in FIG. 2 may be included alone or in combination with the features, components, and arrangement relationships between components described in other drawings of the disclosure. Likewise, all features, components, and/or arrangement relationships between components described in connection with FIGS. 1 and 3 to 16 may be included alone or in combination with the features, components, and arrangement relationships between components described in connection with FIG. 2.

Referring to FIG. 2, the refrigerator 1 according to an embodiment may include at least one input/output device 40, at least one communication device 50, at least one sensor device 60, at least one cooling device 70, at least one display 80, at least one processor 100, and/or at least one memory 101.

According to an embodiment, the input/output device 40 may include any type of user input means for obtaining setting information from the user for controlling the operation of the refrigerator 1. Various user inputs obtained through the input/output device 40 may be transferred to the processor 100 to be described below. In an example, various user inputs obtained through the input/output device 40 may be transmitted to the outside through the communication device 50 to be described below, but the disclosure is not limited thereto.

According to an embodiment, the input device of the input/output device 40 may be installed on a door (e.g., the door 30 of FIG. 1), for the user's convenience. The input device may include any type of user input means including one or more buttons or switches. Setting data (e.g., a desired storage chamber temperature) by the user may be input through the input device. For example, the input device may include a touch panel that receives the user's touch input and generates an electrical signal corresponding to the received touch input, but the disclosure is not limited to a specific type of input unit. In an example, the touch panel constituting the input device may be formed of a transparent material that is positioned on the front surface of a separate display panel provided in the refrigerator 1 and does not distort an image displayed on the display panel. In an example, the input device may include an infrared signal reception unit. The user may remotely input configuration data through a remote controller, and the input configuration data may be received by the input device as an infrared signal. In an example, the input device may include a microphone, and configuration data by the user's voice may be obtained through the microphone.

According to an embodiment, the configuration data (e.g., a desired temperature of the storage compartment) obtained through the input device may be transferred to the processor 100 described below. In an example, the configuration data obtained through the input device may be transmitted to the outside through the communication device described below, but the disclosure is not limited thereto.

According to an embodiment, the refrigerator 1 may include a communication device 50 that supports signal transmission/reception to/from the outside. In an example, the communication device 50 may include a communication circuit and may receive and/or transmit a wired/wireless signal to/from an external wired/wireless communication system, an external server, and/or other devices according to a predetermined wired/wireless communication protocol. In an example, the communication device 50 may include one or more modules to connect the refrigerator 1 to one or more networks. In an example, the communication device 50 may include at least one of a mobile communication module, a wired/wireless Internet module, a short-range communication module, and/or a location information module.

According to an embodiment, the mobile communication module may transmit/receive wireless signals with at least one of an external bracket structure, an external UE, and an external server through the mobile communication network according to any communication protocol among various communication protocols for mobile communication. The wireless signals may include various types of data signals. In an example, the wireless signals may include voice call signals, video call signals, and text/multimedia message signals, but the disclosure is not limited thereto.

According to an embodiment, the wired/wireless Internet module may support wireless LAN (WLAN), wireless-fidelity (Wi-Fi), Wi-Fi direct, digital living network alliance (DLNA), wireless broadband (WiBro), world interoperability for microwave access (WiMAX), high speed downlink packet access (HSDPA), high speed uplink packet access (HSUPA), long term evolution (LTE), or long term evolution-advanced (LTE-A), but is not limited thereto. In an example, the wired/wireless Internet module of the communication device 50 may transmit/receive data according to at least one wired/wireless Internet technology among Internet technologies not listed above.

According to an embodiment, the short-range communication module may be intended for, e.g., short-range communication and may support short-range communication using at least one of Bluetooth, radio frequency identification (RFID), infrared data association (IrDA), ultra-wideband (UWB), ZigBee, near-field communication (NFC), Wi-Fi, Wi-Fi Direct, or wireless universal serial bus (USB) technology. The short-range communication module may support, e.g., wireless communication between the refrigerator 1 and a wireless communication system, between the refrigerator 1 and another device, or between the refrigerator 1 and a network in which the other device is positioned through a short-range wireless communication network.

According to an embodiment, the location information module may be, e.g., a global positioning system (GPS) module or a Wi-Fi module as a module for obtaining the location of the refrigerator 1. When the refrigerator 1 utilizes the GPS module, the refrigerator 1 may receive information about the location of the refrigerator 1 using the signal transmitted from the GPS satellite. When the refrigerator 1 utilizes the Wi-Fi module, the refrigerator 1 may receive information about the location of the refrigerator 1 based on information about a wireless access point (AP) that transmits and receives a wireless signal to and from the Wi-Fi module.

According to an embodiment, the communication device 50 may receive the configuration data signal input by the user on the mobile terminal of the user in the form of a wireless signal according to a predetermined wireless communication protocol. In an example, the communication device 50 may receive information and/or a command for controlling the operation of the refrigerator 1 from an external server in the form of a signal according to a predetermined wired/wireless communication protocol. The communication device 50 may transfer various received signals to the processor 100 to be described below. In an example, the communication device 50 may transmit various data generated or obtained on the refrigerator 1 in the form of a wired/wireless signal according to a predetermined wired/wireless communication protocol, e.g., to a mobile terminal of the user or an external server.

According to an embodiment, the refrigerator 1 may include a sensor device 60. In an example, the sensor device 60 may include a temperature sensor, a proximity sensor, a distance sensor, and/or a camera. However, the types of sensors listed here are merely illustrative and the disclosure is not limited thereto.

According to an embodiment, the temperature sensor may include a plurality of temperature sensors provided inside each storage compartment 10 to sense the temperature inside the storage compartment (e.g., the storage compartment 20 of FIG. 1). A plurality of temperature sensors may be installed in each of the plurality of storage compartments 20 to detect the temperature of each of the storage compartments 20. The electrical signal corresponding to the detected temperature may be transferred to the processor 100. A processor 100 may control operation or stopping of the cooling device 70 to maintain a temperature of the storage compartment constant according to a received current temperature. Each of the plurality of temperature sensors may include a thermistor whose electrical resistance changes according to temperature. In an example, the temperature sensor may include an external temperature sensor that is provided outside the refrigerator 1 (e.g., at one position of the outer case 11 of FIG. 1) to detect the external temperature around the refrigerator 1.

According to an embodiment, the distance sensor may measure the distance to an object, e.g., the user, positioned around the refrigerator 1. The distance sensor may be, e.g., an ultrasonic sensor or an infrared sensor, but is not limited thereto. The distance sensor 62 may detect an object or user around the refrigerator 1 and transfer the detected electrical signal to the processor 100.

According to an embodiment, the proximity sensor may be provided to detect the opening and closing of the door 30. The proximity sensor 63 may detect whether the door 30 is in a state of contacting the main body (e.g., the main body 10 of FIG. 1) to close the storage compartment 20. A plurality of proximity sensors 63 may be installed on a plurality of doors 30, respectively. The proximity sensor 63 may transfer an electrical signal for the detected opening/closing state of the door 30 to the processor 100.

According to an embodiment, the camera is installed inside each storage room 20 to obtain an internal image of each storage compartment 20. In an example, the camera may be provided outside the refrigerator 1 (e.g., at one position of the outer case 11 of FIG. 1) to obtain an external image around the refrigerator 1. The camera may include image sensors that capture an image and convert the image into an electrical signal. The image sensor may include, e.g., a charge-coupled device (CCD) image sensor or a complementary metal oxide semiconductor (CMOS) image sensor. The electrical signal related to the image captured by the camera may be transferred to the processor 100. A camera installed inside the storage compartment 20 may detect opening and closing of the door. For example, the camera may be an infrared camera that may detect human body temperature or external temperature.

According to an embodiment, the refrigerator 1 may include a cooling device 70. In an example, the cooling device 70 may include a compressing system 71 and/or a Peltier element 72. A plurality of cooling devices 70 may be included according to an implementation aspect of the main body 10. For example, a plurality of cooling devices may be included according to an implementation aspect of the storage compartment 20 of the main body 10. For example, cooling devices 70 may be provided in the same number as the storage compartments 20. Alternatively, different types of cooling devices may be included in the storage compartment 20. For example, the refrigerator 1 may include the compressing system 71 and the Peltier element 72 together in a hybrid form.

The compressing system 71 may include a compressor, a condenser, an expander, and an evaporator, and may include refrigerant pipes connecting between them. The refrigerant may circulate between the compressor, the condenser, the expander, and the evaporator through the refrigerant pipes.

The compressor may compress the refrigerant to a high temperature and high pressure state. For example, the compressor may receive electrical energy from outside and compress gaseous refrigerant to high temperature and high pressure using rotational force of an electric motor or the like. The compressor is a variable capacity compressor and may vary capacity by changing frequency according to a drive control command. The compressed refrigerant may be moved to the condenser by the refrigerant pipe. The condenser may condense the compressed refrigerant received from the compressor. The condenser may dissipate heat generated while condensing the refrigerant to the outside of the condenser. The refrigerant condensed while passing through the condenser may be moved to the expander. The condensed refrigerant may be converted to a low temperature and low pressure liquid state while passing through the expander. In an example, the expander may be implemented as an electronic expansion valve capable of adjusting an opening ratio (an electronic expansion valve capable of adjusting a ratio of a cross-sectional area of a valve flow path in a partially opened state to a cross-sectional area of the valve flow path in a fully opened state). In such a case, an amount of refrigerant passing through the expander may be controlled according to the opening ratio of the electronic expansion valve. In an example, the expander may be implemented as a capillary tube device. The liquid refrigerant may pass through the expander and move to the evaporator. In the evaporator, heat exchange with surrounding gas may proceed as the liquid refrigerant evaporates. As the liquid refrigerant evaporates by the evaporator, it absorbs latent heat from surroundings, thereby cooling gas around the evaporator and generating cold air. The generated cold air may be moved to the storage compartment 20 through a flow path provided between an outer case (e.g., the outer case 11 of FIG. 1) and an inner case (e.g., the inner case 12 of FIG. 1). The refrigerant vaporized in the evaporator may move back to the compressor to circulate.

The Peltier element 72, as a thermoelectric element, may cool the storage compartment 20 through heating and cooling actions through the Peltier effect. The Peltier element 72 element generates a cooling effect as thermal energy is released/absorbed when electrons move due to energy level differences between metal and P-N semiconductors. For example, in the Peltier element 72, a P-type semiconductor and an N-type semiconductor are positioned between a first surface and a second surface. (1) At metal A of the first surface, since the P-type semiconductor energy level is low, when electrons move to metal B of the second surface having a high energy level, energy is lost and heat is released. (2) Metal B of the second surface has a high energy level and absorbs heat while gaining energy during electron movement. (3) Since the N-type semiconductor energy level of metal B is high, heat is absorbed while gaining heat when electrons move to metal A of the first surface. (4) Since the energy level of N-type metal A is low, heat is released again while losing energy during electron movement. As such, the first surface becomes in a heating state by operations (1) and (4), and the second surface becomes in a cooling state by operations (2) and (3).

The Peltier element 72 may be manufactured in the form of a module including one or more Peltier individual elements, and one Peltier individual element may be composed of a plurality of semiconductor elements. The Peltier element 72 module may include a plurality of Peltier elements. A driving circuit for operating the Peltier element 72 module includes a voltage source, and one or more Peltier elements may be connected in series. Through a DC/DC converter, duty or frequency variation, the voltage source is controlled to adjust the magnitude of voltage and current applied to the Peltier element to manifest heating or cooling functions.

According to an embodiment, the refrigerator 1 may include a machine room in which at least some components of the cooling device 70 are disposed. The machine room may be configured to be partitioned and insulated from the storage compartment 20 so as to prevent heat generated from the components disposed in the machine room from being transferred to the storage compartment 20. The inside of the machine room may be configured to communicate with the outside of the main body 10 to dissipate heat from components disposed inside the machine room.

According to an embodiment, the refrigerator 1 may include a display 80. In an example, the display 80 may be installed on the door 30. In an example, the display 80 may display various setting data (e.g., a desired storage compartment temperature) obtained through the input/output device 40 and/or the communication device 50 from the user or the outside or operation control information about the refrigerator 1. In an example, the display 80 may display various sensing information (e.g., one or more pieces of temperature information measured by the temperature sensor) obtained from the sensor device 60, the current operating state of the refrigerator 1, and/or various warning/error messages. For example, the display 80 may display a performance degradation message of the refrigerator 1 along with guidance for service application. The display 80 may be one of various visual display means capable of displaying images, characters, numbers, or the like, including a liquid crystal display (LCD) panel, a light emitting diode (LED) panel, an organic light emitting diode (OLED) panel, a micro light emitting diode (uLED) panel, a plasma display panel, or the like, but is not limited to a specific type of display unit. In an example, the display 80 may include a speaker, and may provide each of the above-described information in the form of a voice through the speaker.

According to an embodiment, the refrigerator 1 may include a memory 101 for storing or recording a program and/or data for controlling each component of the refrigerator 1, and a processor 100 for generating a control signal for controlling each component of the refrigerator 1 according to the program and/or data stored in the memory 101 and information obtained from each of the other components.

According to an embodiment, the processor 100 may include a processing circuit and execute commands (or instructions) included in a program (or application) stored in the memory 101. The processor 110 may include, e.g., a micro controller unit (MCU), a central processing unit (CPU), a graphic processing unit (GPU), a neural processing unit (NPU), a sensor processing unit (TPU), a digital signal processor (DSP), an application-specific integrated circuit (ASIC), a field programmable gate array (FPGA), and/or a programmable logic device, but may include a program (or an instruction or Instructions) are not limited as long as they may be executed. The processor 100 may include a main processor and may include one or more sub processors. In an embodiment, the MCU may play a role to drive the cooling device 70 as a sub processor.

According to an embodiment, the memory 101 may include a volatile memory and/or a non-volatile memory, and may include, e.g., a hard disk storage device, RAM, ROM, and/or flash memory, but this is not limited thereto.

According to an embodiment, the memory 101 may include one or more storage media and store various data that may be used to control the operation of each component of the refrigerator 1. The memory 101 may store, e.g., a plurality of application programs used in the refrigerator 1, data for controlling the operation of the refrigerator 1, and instructions. At least some of the application programs stored in the memory 101 may be downloaded from an external server through wireless communication. At least some of the application programs stored in the memory 101 may be stored in the memory 101 from the time of shipment for the basic functions of the refrigerator 1.

According to an embodiment, the memory 101 may store information about abnormal operation occurrence (failure) for a plurality of Peltier elements included in the Peltier element 72. Failure information for the plurality of Peltier elements may be stored and referenced in index form. The memory 101 may store information about temperature control and operation time when the Peltier element 72 operates. The refrigerator 1 may include a plurality of Peltier elements 72, and information about each of the plurality of Peltier elements 72 may be separately stored in the memory 101.

According to an embodiment, the processor 100 may receive various input/setting information, e.g., desired storage compartment temperature information, from the input/output device 40 and/or the communication unit 50 described above. The processor 100 may obtain sensing information from the sensor device 60, such as one or more pieces of temperature information detected by the temperature sensor, a detection signal detected by the distance sensor, door opening/closing information detected by the proximity sensor, and/or image information detected by the camera. In an example, the processor 100 may obtain information about the state of the inside or outside of the storage compartment 20 of the refrigerator 1 by receiving image information obtained by the camera and analyzing the received image information.

According to an embodiment, the processor 100 may generate an operation control command for each component of the refrigerator 1, based on various information received from the input/output device 40, the communication device 50, and/or the sensor device 60. In an example, the processor 100 may control operations of the cooling device 70, such as the compressing system 71 and/or the Peltier element 72, to adjust temperature inside the storage compartment 20. In an example, the processor 100 may control operations of each component of the cooling device 70 using information about temperature of each storage compartment 20 received from temperature sensors. For example, when temperature inside the storage compartment 20 is higher than a preset temperature, the processor 100 may operate the compressing system 71 of the cooling device 70 to lower the temperature of the storage compartment 20. When a proximity sensor of the sensor device 60 detects opening and closing of the door, the Peltier element 72 may be operated to prevent temperature change of the storage compartment 20.

In an example, the processor 100 may generate a command for controlling whether or how to display information through the display 80. In an example, the processor 100 may generate a command to control to turn on the lighting unit of the opened storage compartment 20 based on information about the door 30 opening from the proximity sensor. For example, the processor 100 may generate commands that control the respective operation states of each of the input/output device 40, the communication device 50, the sensor device 60, and/or the lighting device.

In the disclosure, it is disclosed that the processor 100 is a comprehensive component for controlling all the components included in the refrigerator 1, but the disclosure is not limited thereto. In an example, the refrigerator 1 may be configured to include a plurality of processors components that individually control some of the components of the refrigerator 1. In an example, the refrigerator 1 may separately include a processor and a memory for controlling the operation of the cold air supply device 70 according to the output of the temperature sensor. In an example, the refrigerator 1 may separately include a processor and a memory for controlling the operation of the user interface according to a user input. The processor 100 may include a plurality of processors, and the memory 101 may include a plurality of memory devices.

A refrigerator 1 according to an embodiment includes a main body 10 including an accommodation space, a cooling device 70 installed in the main body and supplying cold air to the accommodation space 20, one or more temperature sensors 60 disposed in the main body, a memory 101, and a processor 100 controlling the cooling device 70. The cooling device 70 includes a power source, a plurality of Peltier elements connected in series from the power source, a plurality of switching elements connected in parallel to each of the plurality of Peltier elements, and at least one sensor. The processor may apply power to the power source according to temperature changes detected by the one or more temperature sensors to operate the cooling device and, while current supplied from the power source flows through the plurality of Peltier elements, in response to detecting abnormal operation of a first Peltier element among the plurality of Peltier elements using the at least one sensor, control a first switching element connected in parallel to the first Peltier element so that the current flows except for the first Peltier element.

According to an embodiment, the at least one sensor may be a plurality of voltage sensing sensors respectively corresponding to the plurality of Peltier elements, and the processor may monitor whether real-time sensing voltages for each of the plurality of Peltier elements are within a predetermined normal range using the plurality of voltage sensing sensors while the cooling device operates and, when a sensing voltage of the first Peltier element exceeds the normal range, identify a failure of the first Peltier element.

According to an embodiment, after controlling the first switching element, the processor may identify that voltage of the first Peltier element corresponds to below the normal range using the voltage sensing sensor, thereby identifying that the cooling device is in a normal operating state.

According to an embodiment, the first switching element may allow current to flow in an on state and be disposed to be connected in series between a previous Peltier element of the first Peltier element and a next Peltier element of the first Peltier element according to serial connection order of the plurality of Peltier elements.

According to an embodiment, while the first switching element is in an on state, the processor allows current to be transferred from the previous Peltier element of the first Peltier element to the next Peltier element of the first Peltier element through the first switching element.

According to an embodiment, while sensing voltages of at least some of the plurality of Peltier elements are included in a normal range, at least some switching elements corresponding to the at least some Peltier elements may maintain an off state where current does not flow.

According to an embodiment, the processor may store occurrence of abnormal operation of the first Peltier element in the memory and, when the cooling device restarts, the processor may control the first switching element connected in parallel with the first Peltier element by referring to the memory.

According to an embodiment, the at least one sensor may be a plurality of current sensing sensors respectively corresponding to the plurality of Peltier elements, and the processor may monitor whether real-time sensing currents for each of the plurality of Peltier elements are within a normal range using the plurality of current sensing sensors while the cooling device operates and, when a sensing current of the first Peltier element falls outside the normal range, identify a failure of the first Peltier element.

According to an embodiment, the cooling device may include one or more current blocking switches disposed between the plurality of switches and the plurality of Peltier elements, and in response to detecting abnormal operation of the first Peltier element, the processor may control together the first switching element and a first current blocking switch connected to the first Peltier element.

According to an embodiment, the processor may apply power to the power source according to temperature changes detected by the one or more temperature sensors to operate the cooling device, monitor a first cooling time required until temperature detected by the one or more temperature sensors is included within a normal range, and in response to determining that the first cooling time is greater than an expected time according to temperature control, detect a failure of the refrigerator.

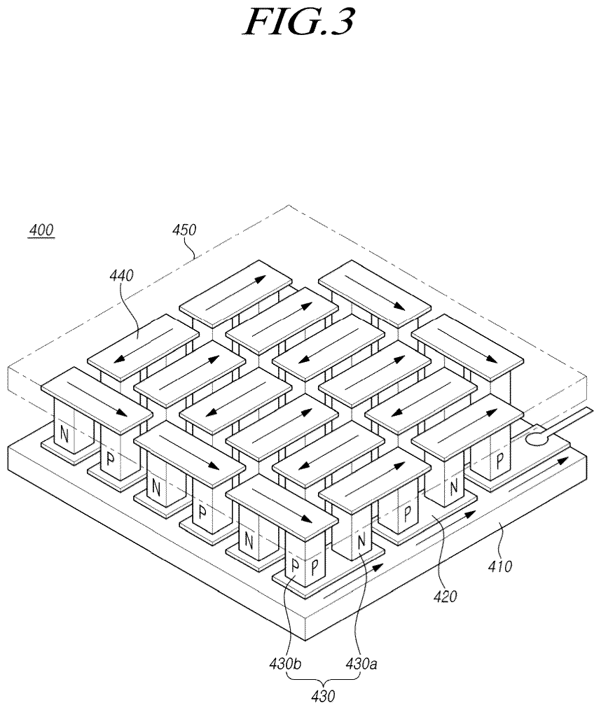

FIG. 3 is a perspective view illustrating a thermoelectric module according to an embodiment.

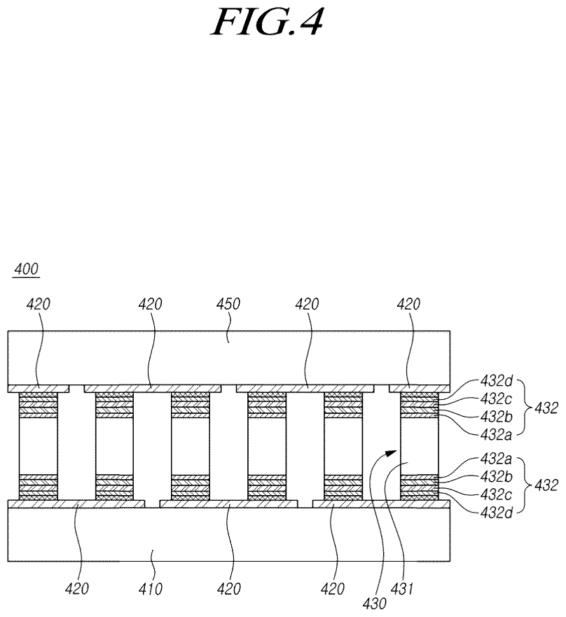

FIG. 4 is a side cross-sectional view illustrating a thermoelectric module according to an embodiment.

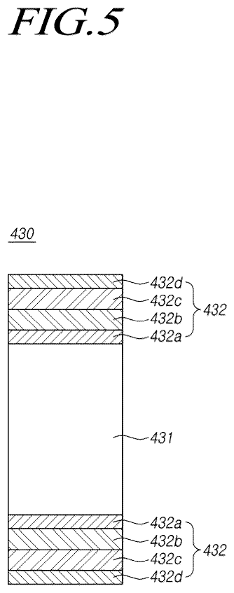

FIG. 5 is a side cross-sectional view illustrating a thermoelectric element according to an embodiment.

All features, components, and/or arrangement relationships between components illustrated in FIGS. 3 to 5 may be included alone or in combination with the features, components, and arrangement relationships between components described in other drawings of the disclosure. Likewise, all features, components, and/or arrangement relationships between components described in connection with FIGS. 1 and 2 and 6 to 16 may be included alone or in combination with the features, components, and arrangement relationships between components described in connection with FIGS. 3 to 5.

Referring to FIGS. 3 to 5, a thermoelectric module 400 according to an embodiment may include at least one of a lower substrate 410, a lower conductive pattern layer 420, a plurality of the thermoelectric elements 430, an upper conductive pattern layer 440, or an upper substrate 450. The lower conductive pattern layer 420 may be disposed on the lower substrate 410. The plurality of the thermoelectric elements 430 may be disposed on the lower conductive pattern layer 420. The upper conductive pattern layer 440 may be disposed on the plurality of the thermoelectric elements 430. The upper substrate 450 may be disposed on the upper conductive pattern layer 440. The thermoelectric module 400 may further include at least one surface mount device (SMD) connector electrically connected to the lower conductive pattern layer 420.

According to an embodiment, the lower substrate 410 may be disposed to support the lower conductive pattern layer 420 and the plurality of the thermoelectric elements 430. The lower substrate 410 may be at least one of a cooling surface and a heat dissipation surface of the thermoelectric module 400. For example, the lower substrate 410 may be a ceramic substrate including at least one of alumina, aluminum nitride (AlN), beryllia (BeO), and silicon nitride (Si₃N₄). For example, the lower substrate 410 may be a metal substrate including at least one of aluminum, copper, stainless steel, and nickel. However, the material of the lower substrate 410 of the disclosure is not limited thereto, and for example, the lower substrate 410 may be implemented with various materials including at least one of sapphire, silicon, silicon carbide (SiC), aluminum silicon carbide composite (AlSiC), and quartz.

According to an embodiment, the lower conductive pattern layer 420 may include at least one lower electrode pattern. The at least one lower electrode pattern may electrically contact at least one thermoelectric element. For example, the at least one lower electrode pattern may electrically contact at least one of an n-type thermoelectric element 430a and a p-type thermoelectric element 430b.

According to an embodiment, the plurality of the thermoelectric elements 430 may include an n-type thermoelectric element 430a and a p-type thermoelectric element 430b. For example, the plurality of the thermoelectric elements 430 may include alternately disposed n-type thermoelectric elements 430a and p-type thermoelectric elements 430b.

According to an embodiment, at least one of the n-type thermoelectric element 430a and the p-type thermoelectric element 430b may include a thermoelectric material layer 431. For example, thermoelectric material layer 431 may include at least one of bismuth telluride (Bi₂Te₃), lead telluride (PbTe), silicon germanium (SiGe), skutterudite, metal halide compounds, and hafnium hydride (HfH₂), but the disclosure is not limited thereto.

According to an embodiment, the upper conductive pattern layer 440 may include at least one upper electrode pattern. The at least one upper electrode pattern may electrically contact at least one thermoelectric element. For example, the at least one upper electrode pattern may electrically contact at least one of the n-type thermoelectric element 430a and the p-type thermoelectric element 430b.

According to an embodiment, the upper substrate 450 may be disposed to support the upper conductive pattern layer 440. The upper substrate 450 may be at least one of a cooling surface and a heat dissipation surface of the thermoelectric module 400. For example, the upper substrate 450 may be a ceramic substrate including at least one of alumina (Al₂O₃), aluminum nitride (AlN), beryllia (BeO), and silicon nitride (Si₃N₄). For example, the upper substrate 450 may be a metal substrate including at least one of aluminum, copper, stainless steel, and nickel. However, the material of the upper substrate 450 of the disclosure is not limited thereto, and for example, the upper substrate 450 may be implemented with various materials including at least one of sapphire, silicon, silicon carbide (SiC), aluminum silicon carbide composite (AlSiC), and quartz.

In an embodiment, when power is supplied to the thermoelectric module 400, power may be delivered to the thermoelectric module 400. For example, when power is supplied to the thermoelectric module 400, current may flow from a positive terminal to the n-type thermoelectric element 430a. For example, when power is supplied to the thermoelectric module 400, current may flow from a negative terminal to the p-type thermoelectric element 430b. For example, when DC voltage is applied from an external power source to the thermoelectric module 400, heat generation and heat absorption may occur at two opposite ends of the plurality of the thermoelectric elements 430.

According to an embodiment, the plurality of the thermoelectric elements 430 may include at least one of the n-type thermoelectric element 430a and the p-type thermoelectric element 430b. The plurality of the thermoelectric elements 430 may include alternately disposed n-type thermoelectric elements 430a and p-type thermoelectric elements 430b.

According to an embodiment, a thermoelectric element 430 may include a thermoelectric material layer 431 and a multilayer diffusion barrier layer 432. The multilayer diffusion barrier layer 432 may be composed of at least three or more layers. In the drawings, the multilayer diffusion barrier layer 432 is illustrated as being composed of 4 layers as an example, but this is for convenience of description and the scope of rights of the disclosure is not limited to the number of diffusion barrier layers illustrated. According to an embodiment, the multilayer diffusion barrier layer may include at least one metal among Co, Ni, Cr, and W.

According to an embodiment, thermoelectric material layer 431 may be composed of a composition including at least two or more of bismuth (Bi), tellurium (Te), cobalt (Co), samarium (Sb), indium (In), and cerium (Ce). Non-limiting examples thereof include Bi—Te-based, Co—Sb-based, Pb—Te-based, Ge—Tb-based, Si—Ge-based, Sb—Te-based, Sm—Co-based, transition metal silicide-based, skutterudite-based, silicide-based, half-Heusler, or combinations thereof.

However, without limitations thereto, thermoelectric material layer 431 may include at least one element selected from the group consisting of transition metals, rare earth elements, group 13 elements, group 14 elements, group 15 elements, and group 16 elements. Here, examples of rare earth elements include Y, Ce, La, etc., and examples of the transition metals may be one or more of Ti, Zr, Hf, V, Nb, Ta, Cr, Mo, W, Mn, Fe, Co, Ni, Cu, Zn, Ag, and Re, examples of the group 13 elements may be one or more of B, Al, Ga, and In, examples of the group 14 elements may be one or more of C, Si, Ge, Sn, and Pb, examples of the group 15 elements may be one or more of P, As, Sb, and Bi, and examples of the group 16 elements may use one or more of S, Se, and Te.

If the thickness of the thermoelectric material layer 431 is too thin and the distance between the heat dissipation portion and the cooling portion is too short, the section where temperature deviation occurs due to interference may be too small. Meanwhile, if the thickness of the thermoelectric material layer 431 is too thick and the distance between the heat dissipation portion and the cooling portion is too long, a thermoelectric element area exhibiting a temperature distribution with high thermoelectric performance index is relatively small, which may lower efficiency.

According to an embodiment, the multilayer diffusion barrier layer 432 may include a first diffusion barrier layer 432a, a second diffusion barrier layer 432b, a third diffusion barrier layer 432c, and a fourth diffusion barrier layer 432d. The first diffusion barrier layer 432a, the second diffusion barrier layer 432b, the third diffusion barrier layer 432c, and the fourth diffusion barrier layer 432d may be sequentially stacked from thermoelectric material layer 431.

According to an embodiment, the first diffusion barrier layer 432a may be disposed on upper and lower surfaces of the thermoelectric material layer 431. The first diffusion barrier layer 432a may include at least one metal among Co, Ni, Cr, and W but, without limitations thereto, may further include metals or metal alloys having diffusion prevention effects in the relevant technical field. For example, the first diffusion barrier layer 432a may include nickel (Ni). The first diffusion barrier layer 432a including nickel may be a layer that assists bonding force. The first diffusion barrier layer 432a may enhance bonding force between adjacent layers during manufacturing of the thermoelectric element 430.

According to an embodiment, a thickness of the first diffusion barrier layer 432a may be 0.1 μm to 2.0 μm. When the first diffusion barrier layer 432a exceeds 2.0 μm, voids may be formed between thermoelectric element 430 and the first diffusion barrier layer 432a due to mutual diffusion during high-temperature area (e.g., 200 degrees Celsius or higher) operation, which may reduce thermoelectric properties.

According to an embodiment, the second diffusion barrier layer 432b may be disposed on the first diffusion barrier layer 432a. The second diffusion barrier layer 432b may be disposed between the first diffusion barrier layer 432a and the third diffusion barrier layer 432c. The second diffusion barrier layer 432b may suppress compound diffusion and void formation to stably maintain thermoelectric properties of the thermoelectric element 430.

According to an embodiment, the second diffusion barrier layer 432b may include a nickel (Ni)-based alloy. The second diffusion barrier layer 432b may have a different nickel-based alloy composition from the third diffusion barrier layer 432c described below. For example, the second diffusion barrier layer 432b may include a nickel-phosphorus (Ni—P) alloy. Here, a content of phosphorus may be 1 wt % to 8 wt %. If the content of phosphorus exceeds 8 wt %, internal stress may increase and adhesion force may deteriorate. However, without limitations thereto, the second diffusion barrier layer 432b may be a Ni-M-based alloy. Here, M may be at least one metal among Al, Co, W, Sn, Sb and Pb.

According to an embodiment, a thickness of the second diffusion barrier layer 432b may be 0.5 μm to 3.0 μm. If the thickness of the second diffusion barrier layer is excessively thick, thermoelectric properties may decrease.

According to an embodiment, the third diffusion barrier layer 432c may be disposed on the second diffusion barrier layer 432b. The third diffusion barrier layer 432c may be disposed between the second diffusion barrier layer 432b and the fourth diffusion barrier layer 432d. The third diffusion barrier layer 432c may enhance bonding with the fourth diffusion barrier layer 432d to contribute to stabilization.

According to an embodiment, the third diffusion barrier layer 432c may include a nickel-based alloy. For example, the third diffusion barrier layer 432c may include a nickel-phosphorus (Ni—P) alloy. Here, a content of phosphorus may be 1 wt % to 8 wt %. If the content of phosphorus exceeds 8 wt %, internal stress may increase and adhesion force may deteriorate.

According to an embodiment, a thickness of the third diffusion barrier layer 432c may be 3.0 μm to 15.0 μm. If the thickness of the third diffusion barrier layer 432c is excessively thick, thermoelectric properties may decrease.

According to an embodiment, the fourth diffusion barrier layer 432d may be disposed on the third diffusion barrier layer 432c. The fourth diffusion barrier layer 432d may increase bonding strength between an electrode and thermoelectric element 430 to enhance durability against thermal stress such as thermal expansion.

According to an embodiment, the fourth diffusion barrier layer 432d may be composed of at least one type of metal. For example, use of nickel may be excluded in the fourth diffusion barrier layer 432d. For example, the fourth diffusion barrier layer 432d may be a nickel-free (Ni-free) metal or alloy including one or more selected from the group consisting of Au, Mo, Ag, Al, and Zn. A thickness of the fourth diffusion barrier layer 432d may be 0.03 μm to 0.5 μm.

According to an embodiment, the first diffusion barrier layer 432a, the second diffusion barrier layer 432b, and the third diffusion barrier layer 432c may each be composed of a nickel (Ni)-containing layer or a Ni alloy layer. The fourth diffusion barrier layer 432d may be composed of a non-nickel-based metal or alloy layer.

According to an embodiment, a total sum of thicknesses of the first diffusion barrier layer 432a, the second diffusion barrier layer 432b, and the third diffusion barrier layer 432c may be 3.0 μm to 20.0 μm.

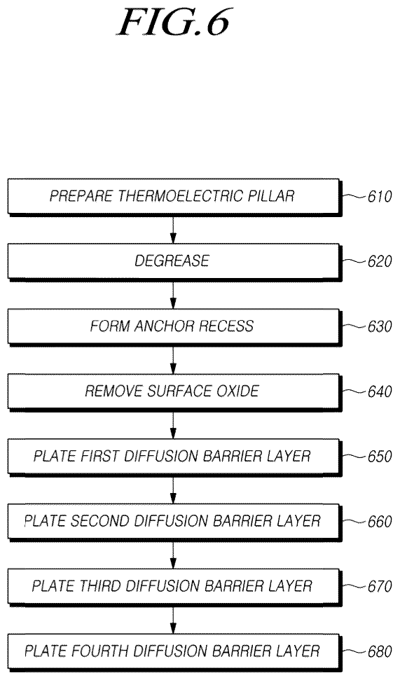

FIG. 6 is a flowchart for describing a method for manufacturing a thermoelectric element according to an embodiment.

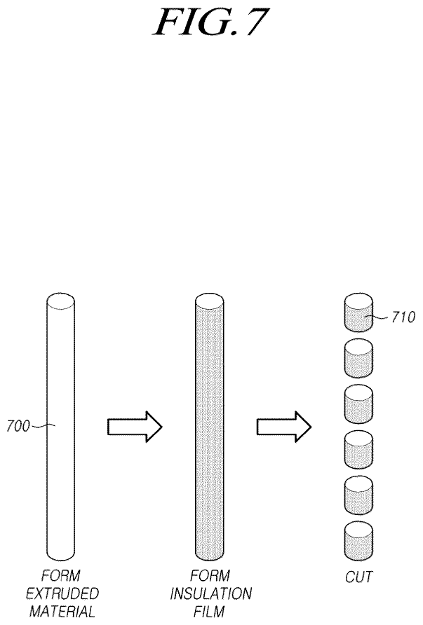

FIG. 7 is an example view illustrating a process of preparing thermoelectric pillars of a thermoelectric element according to an embodiment.

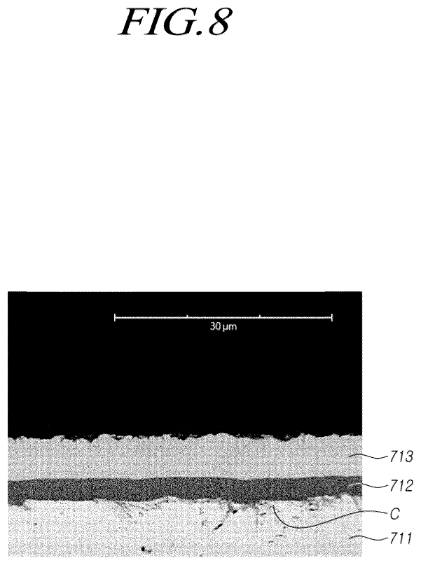

FIG. 8 is a diagram observing a side cross-section of a portion of a general thermoelectric element.

All features, components, and/or arrangement relationships between components illustrated in FIG. 6 may be included alone or in combination with the features, components, and arrangement relationships between components described in other drawings of the disclosure. Likewise, all features, components, and/or arrangement relationships between components described in connection with FIGS. 1 to 5 and 7 to 16 may be included alone or in combination with the features, components, and arrangement relationships between components described in connection with FIG. 6.

Referring to FIG. 6, a method for manufacturing a thermoelectric element (e.g., a thermoelectric element 430 of FIG. 5) according to an embodiment may include a thermoelectric pillar preparation process 610, a degreasing process 620, an anchor recess formation process 630, a surface oxide removal process 640, a first diffusion barrier layer plating process 650, a second diffusion barrier layer plating process 660, a third diffusion barrier layer plating process 670, and a fourth diffusion barrier layer plating process 680.

According to an embodiment, in process 610, a process of preparing a thermoelectric pillar may be performed. The thermoelectric pillar may be referred to as a Peltier leg or a thermoelectric leg. The thermoelectric pillar may be a thermoelectric material layer 431. The process of preparing thermoelectric pillar 710 may include, as illustrated in FIG. 7, an extruded material 700 forming process, a process of forming an insulation film on an outer circumferential surface of the extruded material, and a cutting process. In the process of cutting the thermoelectric pillar 710, fine cracks may be generated at cut portions. Such cracks may act as factors that reduce adhesion force when plating or forming a first diffusion barrier layer (e.g., the first diffusion barrier layer 432a of FIG. 5) as is described below.

According to an embodiment, in process 620, a degreasing process may be performed to remove foreign objects remaining on the surface of the prepared thermoelectric pillar. In the degreasing process, at least one of sodium hydroxide solution, carbonate, and surfactant may be used.

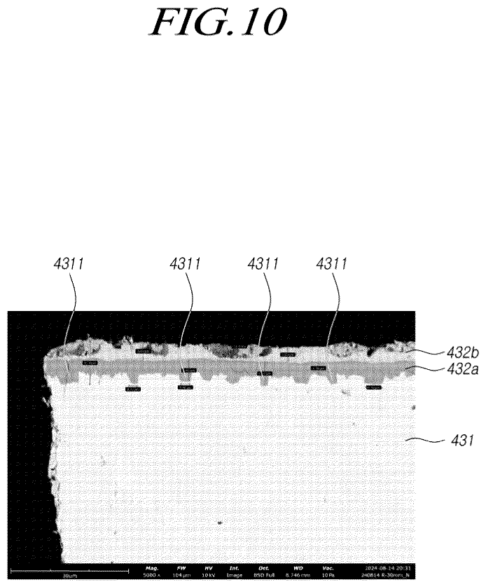

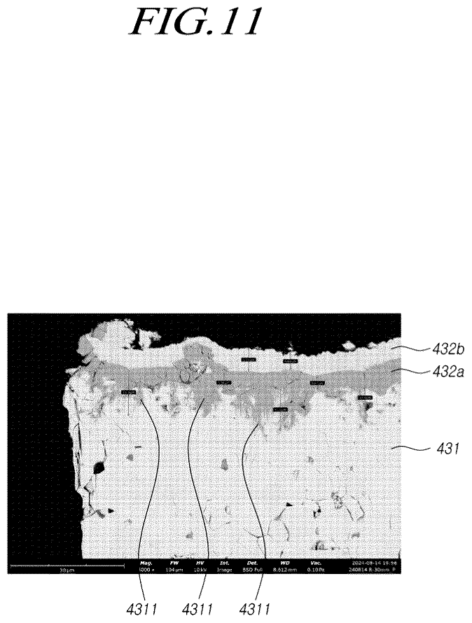

According to an embodiment, in process 630, a process of forming anchor recesses 4311 may be performed. The anchor recesses 4311 may be formed by dissolving cracks formed on the surface of the thermoelectric pillar 710 to expand crack portions. Specific shapes of the anchor recesses are described below in FIGS. 10 and 11.

According to an embodiment, in process 630, the anchor recesses 4311 may be formed using an etching solution. For example, a P-type thermoelectric element may include Bi (bismuth), Te (tellurium), and Sb (antimony). For example, an N-type thermoelectric element may include Bi, Te, and Se (selenium).

In this process, the anchor recesses 4311 may be formed by selectively dissolving Bi commonly included in N-type and P-type thermoelectric elements. To dissolve Bi, a dissolution solution with pH 0 to 2 may be used as a dissolution solution. The dissolution solution may include at least one of nitric acid or sulfuric acid.

According to an embodiment, in process 640, a process of removing surface oxides may be performed. Oxidized material remaining in the anchor recesses from process 630 may be removed in this process. Surface oxides may be removed using ultrasound.

According to an embodiment, in process 650, a process of plating or forming the first diffusion barrier layer 432a may be performed. The first diffusion barrier layer 432a may be plated in thin film form on upper and lower surfaces of the thermoelectric material layer 431. The first diffusion barrier layer 432a may be plated or formed using a barrel electroplating method. The barrel electroplating method may be a method that allows the first diffusion barrier layer 432a to be plated on the thermoelectric material layer 431 with relatively enhanced adhesion force compared to other plating methods. The first diffusion barrier layer 432a may be plated on upper and lower surfaces of the thermoelectric material layer 431 using the barrel electroplating method while side surfaces of the thermoelectric material layer 431 are masked. For example, the first diffusion barrier layer 432a may be plated or formed by a pulse barrel plating method. The first diffusion barrier layer 432a may be, e.g., a nickel layer.

According to an embodiment, in process 660, a process of plating or forming the second diffusion barrier layer 432b may be performed. The second diffusion barrier layer 432b may be plated or formed on the first diffusion barrier layer 432a. The second diffusion barrier layer 432b may be plated or formed using an electroless plating method. The second diffusion barrier layer 432b may be plated with a nickel-phosphorus (Ni—P) alloy. Here, a content of phosphorus (P) may be 1 wt % to 8 wt %.

According to an embodiment, in process 670, a process of plating or forming the third diffusion barrier layer 432c may be performed. The third diffusion barrier layer 432c may be plated or formed on the second diffusion barrier layer 432b. The third diffusion barrier layer 432c may be plated or formed using an electroless plating method. The third diffusion barrier layer 432c may be plated with a nickel-phosphorus (Ni—P) alloy. Here, a content of phosphorus (P) may be 1 wt % to 8 wt %.

According to an embodiment, in process 680, a process of plating or forming the fourth diffusion barrier layer 432d may be performed. The fourth diffusion barrier layer 432d may be plated or formed on the third diffusion barrier layer 432c.

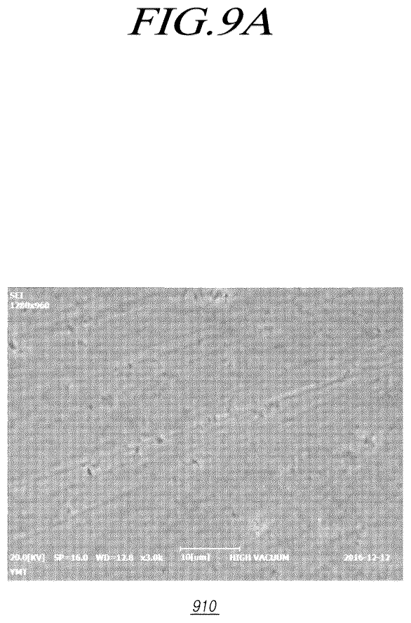

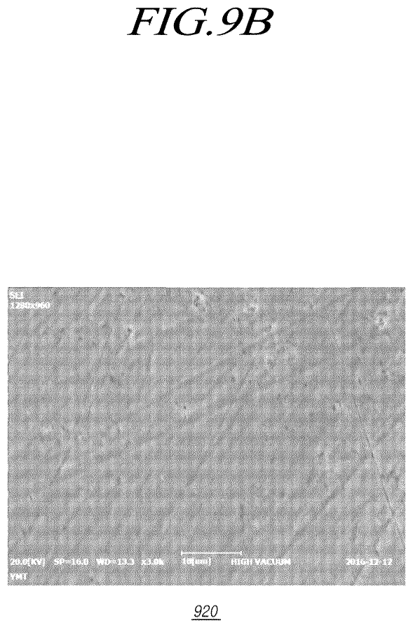

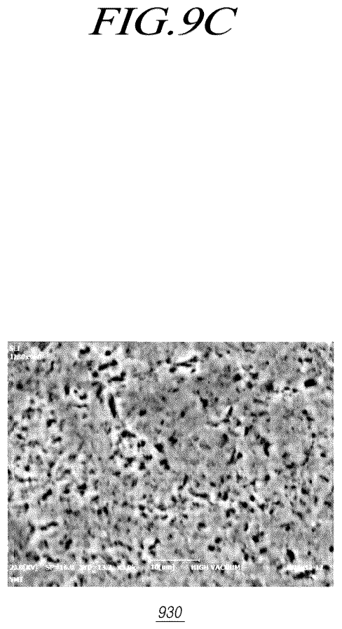

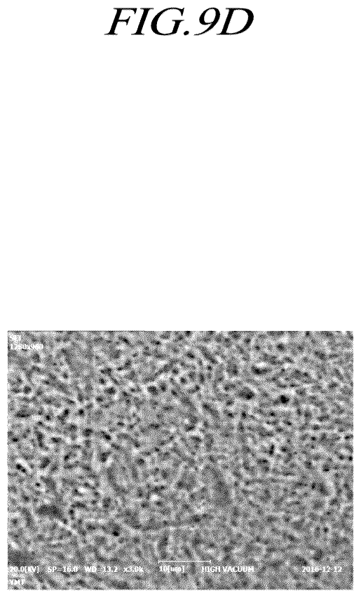

FIGS. 9A, 9B, 9C, and 9D are experimental examples observing a process of surface changes during manufacturing of a thermoelectric element according to an embodiment.

All features, components, and/or arrangement relationships between components illustrated in FIGS. 9A, 9B, 9C, and 9D may be included alone or in combination with the features, components, and arrangement relationships between components described in other drawings of the disclosure. Likewise, all features, components, and/or arrangement relationships between components described in connection with FIGS. 1 to 8 and 10 to 16 may be included alone or in combination with the features, components, and arrangement relationships between components described in connection with FIGS. 9A, 9B, 9C, and 9D.

Image 910 is an image of observing an upper surface of the thermoelectric material layer 431 with a microscope in a state before thermoelectric pillar is degreased in process 610 of FIG. 6. Image 920 is an image of observing an upper surface of the thermoelectric material layer 431 with a microscope in a state after degreasing the surface in process 620. Image 930 is an image of observing an upper surface of the thermoelectric material layer 431 with a microscope in a state after dissolving crack portions on the surface in process 630. Image 940 is an image observed with a microscope after removing oxidized material on the surface in process 640.

As illustrated in FIGS. 9A, 9B, 9C, and 9D, when crack portions are dissolved in process 630, cracks may be expanded to form anchor recesses 4311. In the process of forming anchor recesses 4311, it may be identified that oxidized material remains in the form of black dots as illustrated in image 930. When oxidized material is removed, a state in which foreign objects inside the anchor recesses 4311 are removed may be achieved as illustrated in image 940.

FIG. 10 is an experimental example of observing a side cross-sectional view illustrating a p-type thermoelectric element according to an embodiment with an electron microscope.

FIG. 11 is an experimental example of observing a side cross-sectional view illustrating an n-type thermoelectric element according to an embodiment with an electron microscope.

All features, components, and/or arrangement relationships between components illustrated in FIGS. 10 and 11 may be included alone or in combination with the features, components, and arrangement relationships between components described in other drawings of the disclosure. Likewise, all features, components, and/or arrangement relationships between components described in connection with FIGS. 1 to 9D and 12 to 16 may be included alone or in combination with the features, components, and arrangement relationships between components described in connection with FIGS. 10 and 11.

Referring to FIGS. 10 and 11, a thermoelectric element 430 may include at least one of a thermoelectric material layer 431, a first diffusion barrier layer 432a, a second diffusion barrier layer 432b, a third diffusion barrier layer (e.g., the third diffusion barrier layer 432c of FIG. 5), or a fourth diffusion barrier layer (e.g., the fourth diffusion barrier layer 432d of FIG. 5).

According to an embodiment, the anchor recesses 4311 may be formed on an upper surface or a lower surface of the thermoelectric material layer 431. FIGS. 10 and 11 illustrate anchor recesses 4311 formed on an upper surface of the thermoelectric material layer 431 as an example.

According to an embodiment, the anchor recesses 4311 may have a depth of 0.1 μm to 10.0 μm. The anchor recesses 4311 may be formed based on cracks formed during a cutting process. When the depth of the anchor recesses 4311 exceeds 10 μm, surface roughness may become rough and appearance quality may deteriorate. The thermoelectric element of the disclosure forms anchor recesses 4311 using cracks generated during a cutting process, and has an advantage of relatively high tensile strength despite low depth of the anchor recesses 4311.

According to an embodiment, the anchor recesses 4311 may have a width of 0.1 μm to 10.0 μm.

According to an embodiment, the first diffusion barrier layer 432a is disposed on the thermoelectric material layer 431 so that a portion thereof may penetrate into the plurality of anchor recesses 4311. In the case of cracks (e.g., crack C of FIG. 8) generated during cutting of the thermoelectric material layer 431, as illustrated in FIG. 8, it is difficult for the first diffusion barrier layer 432a to penetrate, and as a result, durability of the thermoelectric element 430 may be decreased. In the disclosure, by expanding cracks to form anchor recesses 4311, a portion of the first diffusion barrier layer 432a may flow into the anchor recesses 4311, and as a result, contact area between the first diffusion barrier layer 432a and thermoelectric material layer 431 may increase, thereby enhancing adhesion force.

According to an embodiment, shapes of the plurality of anchor recesses 4311 are not limited to specific shapes. The plurality of anchor recesses 4311 may have, e.g., dendrite or rod shapes. For example, as illustrated in FIG. 10, the anchor recesses 4311 may have a rod shape. For example, as illustrated in FIG. 11, the anchor recesses 4311 may have a dendrite shape.

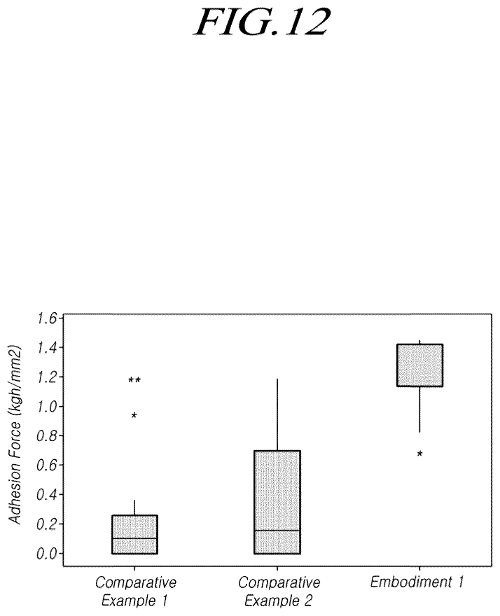

FIG. 12 is an experimental example for identifying an enhancement degree of adhesion force of a thermoelectric element according to an embodiment.

All features, components, and/or arrangement relationships between components illustrated in FIG. 12 may be included alone or in combination with the features, components, and arrangement relationships between components described in other drawings of the disclosure. Likewise, all features, components, and/or arrangement relationships between components described in connection with FIGS. 1 to 11 and 13A to 16 may be included alone or in combination with the features, components, and arrangement relationships between components described in connection with FIG. 12.

TABLE 1

| | | adhesion force | adhesion force | |
|---|---|---|---|---|
| | | (kgf/mm²) of | (kgf/mm²) of | adhesion force |
| | | Comparative | Comparative | (kgf/mm²) of |
| Items | No | Example 1 | Example 2 | embodiment |
| n-type | 1 | 0.079 | 1.180 | 1.435 |
| thermoelectric | 2 | 0.098 | 0.934 | 0.826 |
| element | 3 | 0.128 | 0.560 | 1.297 |
| | 4 | 0.181 | 0.590 | 1.415 |
| | 5 | 0.098 | 0.737 | 1.415 |
| | 6 | 0.059 | 0.374 | 1.435 |
| | 7 | 0 | 0.413 | 0.678 |
| | 8 | 0 | 1.180 | 1.337 |
| | 9 | 0 | 0.157 | 1.101 |
| | 10 | 0 | 1.180 | 1.415 |
| p-type | 11 | 0.118 | 0.128 | 1.258 |
| thermoelectric | 12 | 0.197 | 0 | 1.435 |
| element | 13 | 0.265 | 0 | 1.415 |
| | 14 | 0.059 | 0 | 1.415 |
| | 15 | 1.180 | 0 | 1.415 |
| | 16 | 1.180 | 0 | 1.415 |
| | 17 | 0.944 | 0 | 1.003 |
| | 18 | 0.364 | 0 | 1.435 |
| | 19 | 0 | 0 | 1.022 |
| | 20 | 0 | 0 | 1.415 |

Table 1 is data comparing adhesion forces of an embodiment that forms anchor recesses 4311 using through cracks with Comparative Examples 1 and 2. Table 1 is summarized and presented as a graph in FIG. 12.

In Table 1, the adhesion force of Comparative Example 1 is adhesion force measured based on plating tensile force when the first diffusion barrier layer was plated while through cracks were maintained without configuring any particular recesses on the surface of the thermoelectric material layer. The adhesion force of Comparative Example 2 is adhesion force measured based on plating tensile force when the first diffusion barrier layer was plated after forming physical recesses by irradiating laser on the surface of the thermoelectric material layer. The adhesion force of the embodiment is adhesion force measured based on plating tensile force when the first diffusion barrier layer was plated after forming anchor recesses by expanding through cracks.

The average adhesion force of Comparative Example 1 is 0.247 kgf/mm², the average adhesion force of Comparative Example 2 is 0.372 kgf/mm², and average adhesion force of the thermoelectric element 430 according to an embodiment of the disclosure is 1.129 kgf/mm², as identified through experiments. It may be identified through experiments that the embodiment has about 518% increased adhesion force compared to Comparative Example 1.

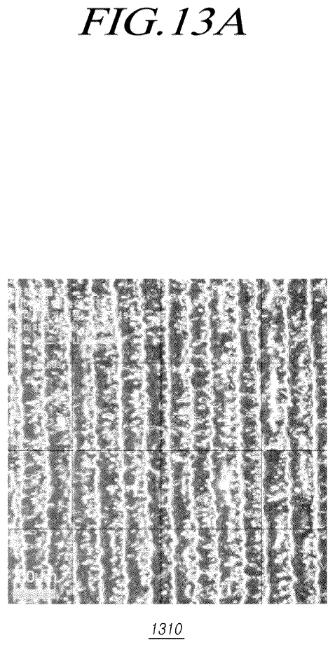

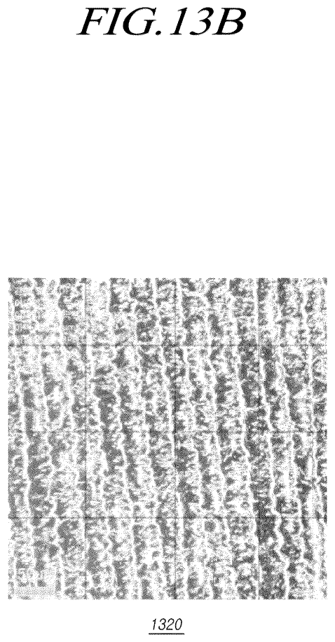

FIGS. 13A and 13B are experimental examples for observing surface roughness when anchor recesses are formed by a laser irradiation method.

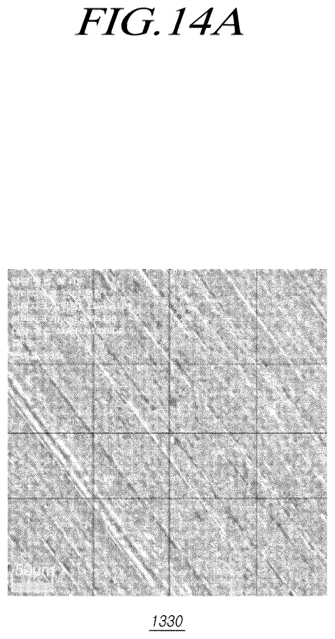

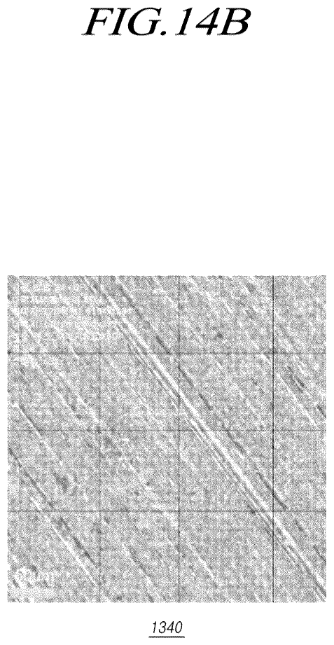

FIGS. 14A and 14B are experimental examples for observing surface roughness of a thermoelectric element according to an embodiment.

All features, components, and/or arrangement relationships between components illustrated in FIGS. 14A and 14B may be included alone or in combination with the features, components, and arrangement relationships between components described in other drawings of the disclosure. Likewise, all features, components, and/or arrangement relationships between components described in connection with FIGS. 1 to 12 and 15A to 16 may be included alone or in combination with the features, components, and arrangement relationships between components described in connection with FIGS. 14A and 14B.

TABLE 2

| | | surface | surface | |
|---|---|---|---|---|
| | | roughness | roughness | surface |
| | | (Ra) of | (Ra) of | roughness |
| | | Comparative | Comparative | (Ra) of |
| Items | No | Example 1 | Example 2 | embodiment |
| n-type | 1 | 0.331 | 1.061 | 0.358 |
| thermoelectric | 2 | 0.338 | 1.007 | 0.330 |
| element | 3 | 0.303 | 0.936 | 0.353 |
| | 4 | 0.188 | 0.331 | 0.325 |
| | 5 | 0.191 | 0.399 | 0.338 |
| | 6 | 0.142 | 0.357 | 0.330 |
| p-type | 7 | 0.382 | 0.948 | 0.419 |
| thermoelectric | 8 | 0.371 | 0.927 | 0.469 |
| element | 9 | 0.392 | 1.212 | 0.379 |
| | 10 | 0.406 | 0.394 | 0.335 |
| | 11 | 0.164 | 0.469 | 0.447 |
| | 12 | 0.345 | 0.555 | 0.379 |

Table 2 is data comparing adhesion forces of an embodiment that forms anchor recesses 4311 using through cracks with Comparative Examples 1 and 2.

In Table 2, the surface roughness of Comparative Example 1 is surface roughness of the thermoelectric material layer surface in a state in which through cracks are maintained without configuring any particular recesses on the thermoelectric material layer surface. The surface roughness of Comparative Example 2 is surface roughness of the thermoelectric material layer surface after forming physical recesses by irradiating laser on the thermoelectric material layer surface. The surface roughness of the embodiment is surface roughness of the thermoelectric material layer surface after forming anchor recesses by expanding through cracks.

In the case of Comparative Example 1, experimental values of average roughness of 0.343 for p-type thermoelectric elements and average roughness of 0.249 for n-type thermoelectric elements were obtained. In the case of Comparative Example 2, the average roughness of p-type thermoelectric elements is 0.751 and average roughness of n-type thermoelectric elements is 0.683, identifying that average roughness significantly increased compared to Comparative Example 1. In the embodiment, the average roughness of p-type thermoelectric elements is 0.405 and average roughness of n-type thermoelectric elements is 0.339, identifying that average roughness did not greatly increase compared to Comparative Example 1. When anchor recesses are formed using the manufacturing process according to an embodiment (see FIG. 6), existing cracks are used as anchors, thereby enhancing adhesion force without greatly increasing surface roughness.

FIGS. 13A and 13B are images 1310, 1320 observing surface states of the thermoelectric material layer of Comparative Example 2. FIGS. 14A and 14B are images 1330, 1340 observing surface states of the thermoelectric material layer 431 of the embodiment. When comparing images observed with a microscope, it may be identified that Comparative Example 2 has a rougher surface than the embodiment.

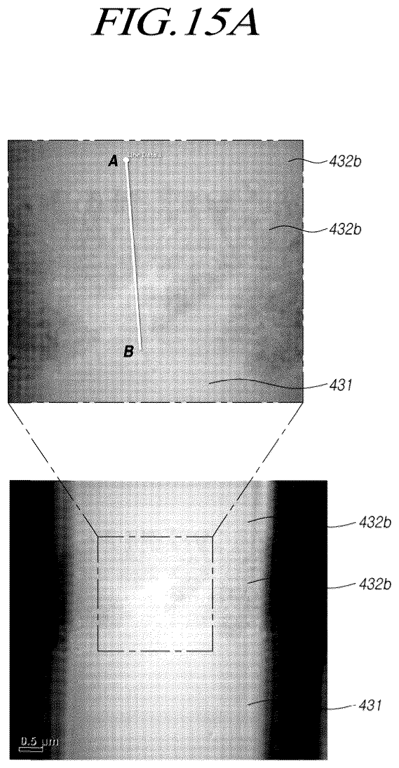

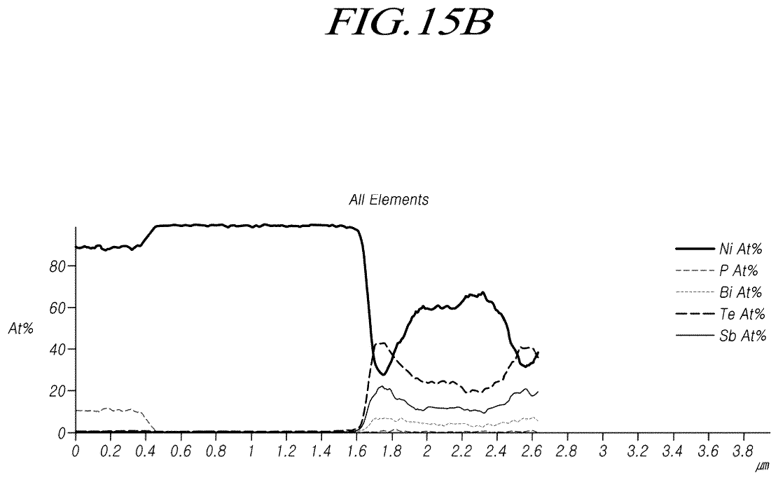

FIG. 15A is an experimental example of observing a side cross-section of a thermoelectric element according to an embodiment.

FIG. 15B is a graph measuring element content of a portion corresponding to line A-B of FIG. 15A.

All features, components, and/or arrangement relationships between components illustrated in FIGS. 15A and 15B may be included alone or in combination with the features, components, and arrangement relationships between components described in other drawings of the disclosure. Likewise, all features, components, and/or arrangement relationships between components described in connection with FIGS. 1 to 14B and 16 may be included alone or in combination with the features, components, and arrangement relationships between components described in connection with FIGS. 15A and 15B.

The image illustrated in FIG. 15A is a side cross-section of a portion of the thermoelectric element 430 manufactured by the manufacturing process of FIG. 6.

The graph of FIG. 15B is a graph using Fe-SEM line profile analysis. FIG. 15B illustrates a graph of the ratio of elements included at each position starting from point A of FIG. 15A. The length of line A-B may be about 2.6 μm.

Referring to the graph of FIG. 15B, it may be identified that no phosphorus (P) component is detected in the first diffusion barrier layer 432a, and it exhibits a different microstructural phase from the nickel-phosphorus (Ni—P) alloy plating layer of the second diffusion barrier layer. Further, it may be identified that gaps (or voids) are not formed between the first diffusion barrier layer 432a and thermoelectric material layer 431 despite irregularities formed by anchor recesses 4311 on the surface of the thermoelectric material layer 431. In other words, a thermoelectric element 430 according to an embodiment of the disclosure may have a structure that enhances adhesion force without voids by forming anchor recesses 4311.

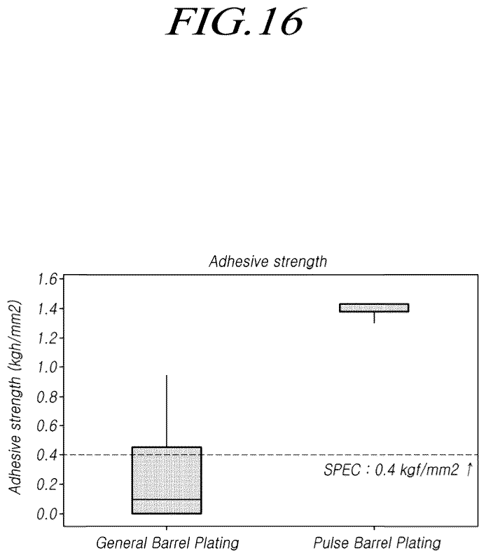

FIG. 16 is an experimental example for identifying adhesion force according to a method of plating a first diffusion barrier layer in a thermoelectric element according to an embodiment.

All features, components, and/or arrangement relationships between components illustrated in FIG. 16 may be included alone or in combination with the features, components, and arrangement relationships between components described in other drawings of the disclosure. Likewise, all features, components, and/or arrangement relationships between components described in connection with FIGS. 1 to 15B may be included alone or in combination with the features, components, and arrangement relationships between components described in connection with FIG. 16.

TABLE 3

| | | general electric | pulse barrel |
|---|---|---|---|
| | | barrel adhesion | adhesion force |
| Items | No | force (kgf/mm²) | (kgf/mm²) |
| n-type | 1 | 0.000 | 1.268 |
| thermoelectric | 2 | 0.049 | 1.081 |
| element | 3 | 0.049 | 1.307 |
| | 4 | 0.197 | 1.435 |
| | 5 | 0.000 | 1.376 |
| | 6 | 0.000 | 1.435 |
| | 7 | 0.020 | 1.435 |
| | 8 | 0.010 | 1.435 |
| | 9 | 0.147 | 1.415 |
| | 10 | 0.000 | 1.189 |
| p-type | 11 | 0.413 | 1.435 |
| thermoelectric | 12 | 0.629 | 1.435 |
| element | 13 | 0.521 | 1.435 |
| | 14 | 0.953 | 1.376 |
| | 15 | 0.452 | 1.435 |
| | 16 | 0.000 | 1.435 |
| | 17 | 0.586 | 1.415 |
| | 18 | 0.000 | 1.435 |
| | 19 | 0.256 | 1.435 |
| | 20 | 0.157 | 1.435 |

Table 3 is a table organizing experimental values measuring adhesion force between the first diffusion barrier layer 432a and thermoelectric material layer 431 when using a general electric barrel plating method and when using a pulse barrel plating method using pulse current in relation to a method of plating the first diffusion barrier layer 432a. Table 3 is summarized and presented as a graph in FIG. 16.

When the first diffusion barrier layer 432a was plated on the thermoelectric material layer 431 using a general electric barrel plating method, the average adhesion force is 0.222 kgf/mm² and, when the first diffusion barrier layer 432a was plated on the thermoelectric material layer 431 using a pulse barrel plating method, the average adhesion force is 1.382 kgf/mm². When barrel plating is performed using pulse current, it may be identified through experiments that adhesion force is about 622% increased compared to general barrel plating.

A thermoelectric element 430 according to an embodiment may include a thermoelectric material layer 431 forming a plurality of anchor recesses 4311 on upper and lower surfaces thereof, the anchor recesses having a width of 0.1 μm to 10 μm and being formed based on cracks, and a first diffusion barrier layer 432a disposed on the thermoelectric material layer 431, wherein a portion of the first diffusion barrier layer penetrates into the plurality of anchor recesses 4311.

According to an embodiment, the plurality of anchor recesses 4311 may have a dendrite or rod shape.

According to an embodiment, the plurality of anchor recesses 4311 may have a depth of 0.1 μm to 10 μm.

According to an embodiment, the first diffusion barrier layer 432a may include nickel.

According to an embodiment, the first diffusion barrier layer 432a may have a thickness of 0.1 μm to 2.0 μm.

According to an embodiment, the thermoelectric elements 430 may further include a second diffusion barrier layer 432b including a nickel-phosphorus alloy structure and disposed on the first diffusion barrier layer 432a, and a third diffusion barrier layer 432c including a nickel-phosphorus alloy structure and disposed on the second diffusion barrier layer 432b.

According to an embodiment, a total thickness of the first diffusion barrier layer 432a, the second diffusion barrier layer 432b, and the third diffusion barrier layer 432c may be 3.0 μm to 20.0 μm.

According to an embodiment, 20% to 30% of a total volume of the first diffusion barrier layer 432a, the second diffusion barrier layer 432b, and the third diffusion barrier layer 432c may penetrate into the plurality of anchor recesses 4311.

According to an embodiment, a phosphorus (P) content of the second diffusion barrier layer 432b may be 1 wt % to 8 wt %, and a phosphorus (P) content of the third diffusion barrier layer 432c may be 1 wt % to 8 wt %.

According to an embodiment, thermoelectric material layer 431 may include Bi. A Bi weight content of portions forming the plurality of anchor recesses 4311 may be less than an average Bi weight content of the thermoelectric material layer 431.

A refrigerator according to an embodiment may include a storage compartment 20, a main body 10 including the storage compartment 20, and a cold air supply device 70 configured to supply cold air to the storage compartment 20 and including a thermoelectric module 400. The thermoelectric module 400 may include a lower substrate 410, a lower conductive pattern layer 420 disposed on the lower substrate 410, a plurality of thermoelectric elements 430 disposed on the lower conductive pattern layer 420, an upper conductive pattern layer 440 disposed on the thermoelectric elements 430, and an upper substrate 450 formed on the upper conductive pattern layer 440. The thermoelectric elements 430 may include a plurality of thermoelectric material layers 431 forming a plurality of anchor recesses 4311 on upper and lower surfaces thereof, the anchor recesses having a width of 0.1 μm to 10.0 μm and being formed based on cracks, and a first diffusion barrier layer 432a disposed on the plurality of thermoelectric material layers 431, wherein a portion of the first diffusion barrier layer penetrates into the plurality of anchor recesses 4311.

According to an embodiment, the plurality of anchor recesses 4311 may have a dendrite or rod shape.

According to an embodiment, the plurality of anchor recesses 4311 may have a depth of 0.1 μm to 10 μm.

According to an embodiment, the first diffusion barrier layer 432a may include nickel.

According to an embodiment, the first diffusion barrier layer 432a may have a thickness of 0.1 μm to 2.0 μm.

According to an embodiment, the thermoelectric elements 430 may further include a second diffusion barrier layer 432b including a nickel-phosphorus alloy structure and disposed on the first diffusion barrier layer 432a, and a third diffusion barrier layer 432c including a nickel-phosphorus alloy structure and disposed on the second diffusion barrier layer 432b.

According to an embodiment, a total thickness of the first diffusion barrier layer 432a, the second diffusion barrier layer 432b, and the third diffusion barrier layer 432c may be 3.0 μm to 20.0 μm.

According to an embodiment, 20% to 30% of a total volume of the first diffusion barrier layer 432a, the second diffusion barrier layer 432b, and the third diffusion barrier layer 432c may penetrate into the plurality of anchor recesses 4311.

According to an embodiment, a phosphorus (P) content of the second diffusion barrier layer 432b may be 1 wt % to 8 wt %, and a phosphorus (P) content of the third diffusion barrier layer 432c may be 1 wt % to 8 wt %.

According to an embodiment, thermoelectric material layer 431 may include Bi. A Bi weight content of portions forming the plurality of anchor recesses 4311 may be less than an average Bi weight content of the thermoelectric material layer 431.

In the disclosure, the above-described description has been made mainly of specific embodiments, but the disclosure is not limited to such specific embodiments, but should rather be appreciated as covering all various modifications, equivalents, and/or substitutes of various embodiments.

1. A thermoelectric element comprising:
a thermoelectric material layer including a plurality of anchor recesses on upper and lower surfaces of the thermoelectric material layer, the plurality of anchor recesses having a width of 0.1 μm to 10 μm and being formed on cracks on the upper and lower surfaces of the thermoelectric material layer; and
a first diffusion barrier layer disposed on the thermoelectric material layer, wherein a portion of the first diffusion barrier layer penetrates into the plurality of anchor recesses.

2. The thermoelectric element of claim 1, wherein
at least a portion of anchor recesses of the plurality of anchor recesses have a dendrite or rod shape.

3. The thermoelectric element of claim 1, wherein
at least a portion of the plurality of anchor recesses have a depth of 0.1 μm to 10 μm.

4. The thermoelectric element of claim 1, wherein
the first diffusion barrier layer includes nickel.

5. The thermoelectric element of claim 1, wherein
the first diffusion barrier layer has a thickness of 0.1 μm to 2.0 μm.

6. The thermoelectric element of claim 1, further comprising:
a second diffusion barrier layer including a nickel-phosphorus alloy structure, and disposed on the first diffusion barrier layer; and
a third diffusion barrier layer including a nickel-phosphorus alloy structure, and disposed on the second diffusion barrier layer.

7. The thermoelectric element of claim 6, wherein
a total thickness of the first diffusion barrier layer, the second diffusion barrier layer, and the third diffusion barrier layer is 3.0 μm to 20.0 μm.

8. The thermoelectric element of claim 6, wherein
20% to 30% of a total volume of the first diffusion barrier layer, the second diffusion barrier layer, and the third diffusion barrier layer penetrates into the plurality of anchor recesses.

9. The thermoelectric element of claim 6, wherein
a phosphorus content of the second diffusion barrier layer is 1 wt % to 8 wt %, and
a phosphorus content of the third diffusion barrier layer is 1 wt % to 8 wt %.

10. The thermoelectric element of claim 1, wherein
the thermoelectric material layer includes bismuth, and
a bismuth weight content of portions of the thermoelectric material layer forming the plurality of anchor recesses is less than an average bismuth weight content of the thermoelectric material layer.

11. A refrigerator, comprising:
a main body;
a storage compartment in the main body; and
a cold air supply device configured to supply cold air to the storage compartment, the cold air supply device including a thermoelectric module,
wherein the thermoelectric module includes:
a lower substrate,
a lower conductive pattern layer disposed on the lower substrate,
a plurality of thermoelectric elements disposed on the lower conductive pattern layer,
an upper conductive pattern layer disposed on the plurality of thermoelectric elements, and
an upper substrate disposed on the upper conductive pattern layer, and
each thermoelectric element of the plurality of thermoelectric elements includes:
a thermoelectric material layer including a plurality of anchor recesses on upper and lower surfaces of the thermoelectric material layer, the plurality of anchor recesses having a width of 0.1 μm to 10.0 μm and being formed on cracks on the upper and lower surfaces of the thermoelectric material layer, and
a first diffusion barrier layer disposed on the thermoelectric material layer, wherein a portion of the first diffusion barrier layer penetrates into the plurality of anchor recesses.

12. The refrigerator of claim 11, wherein
at least a portion of anchor recesses of the plurality of anchor recesses have a dendrite or rod shape.

13. The refrigerator of claim 11, wherein
at least a portion of the plurality of anchor recesses have a depth of 0.1 μm to 10 μm.

14. The refrigerator of claim 11, wherein
the first diffusion barrier layer includes nickel.

15. The refrigerator of claim 11, wherein
the first diffusion barrier layer has a thickness of 0.1 μm to 2.0 μm.

16. The refrigerator of claim 11, wherein
each thermoelectric element of the plurality of thermoelectric elements includes:
a second diffusion barrier layer including a nickel-phosphorus alloy structure, and disposed on the first diffusion barrier layer, and
a third diffusion barrier layer including a nickel-phosphorus alloy structure, and disposed on the second diffusion barrier layer.

17. The refrigerator of claim 16, wherein
a total thickness of the first diffusion barrier layer, the second diffusion barrier layer, and the third diffusion barrier layer is 3.0 μm to 20.0 μm.

18. The refrigerator of claim 16, wherein
20% to 30% of a total volume of the first diffusion barrier layer, the second diffusion barrier layer, and the third diffusion barrier layer penetrates into the plurality of anchor recesses.

19. The refrigerator of claim 16, wherein
a phosphorus content of the second diffusion barrier layer is 1 wt % to 8 wt %, and
a phosphorus content of the third diffusion barrier layer is 1 wt % to 8 wt %.

20. The refrigerator of claim 11, wherein
the thermoelectric material layer includes bismuth, and
a bismuth weight content of portions of the thermoelectric material layer forming the plurality of anchor recesses is less than an average bismuth weight content of the thermoelectric material layer.
